(19) United States
(12) Patent Application Publication
(10) Pub. No.: US 2026/0057831 A1
(43) Pub. Date: Feb. 26, 2026

(54) DISPLAY DEVICE AND ELECTRONIC DEVICE INCLUDING DISPLAY DEVICE

(71) Applicant: Samsung Display Co., LTD., Yongin-si (KR)

(72) Inventors: Jun Ki JEONG, Yongin-si (KR); Young Wan SEO, Yongin-si (KR); Jong Yeop AN, Yongin-si (KR)

(21) Appl. No.: 19/189,690

(22) Filed: Apr. 25, 2025

(30) Foreign Application Priority Data
Aug. 21, 2024 (KR) 10-2024-0112174

(51) Int. Cl. G09G 3/3233; H10K 59/121; H10K 59/131

(52) U.S. Cl. CPC G09G 3/3233; H10K 59/1216; H10K 59/131; G09G 2300/0426; G09G 2300/0819; G09G 2300/0842; G09G 2320/0233

(57) ABSTRACT

A display device includes: pixels each including sub-pixels; and a first and second DC lines. Each of the sub-pixels includes: a light emitting element; and a sub-pixel circuit connected to the light emitting element and the first and second DC lines. The sub-pixel circuit includes: a first transistor, where a gate electrode of the first transistor is connected to a first node and one electrode of the first transistor is connected to a second node; a storage capacitor connected between the first node and the second node; a first hold capacitor forming a first hold capacitance between the second node and the first DC line; and a second hold capacitor forming a second hold capacitance between the second node and the second DC line. In sub-pixels which provide light of a same color, a sum of the first capacitance is equal to a sum of the second hold capacitance.

This application claims priority to Korean Patent Application No.10-2024-0112174, filed on Aug. 21, 2024, and all the benefits accruing therefrom under 35 U.S. C. § 119, the content of which in its entirety is herein incorporated by reference.

### BACKGROUND

### 1. Field

The disclosure generally relates to a display device and an electronic device including a display device.

### 2. Description of the Related Art

Recently, as interest in information displays is increased, research and development of display devices have been continuously conducted. A display device may include sub-pixels each including a pixel circuit and a light emitting element electrically connected to the pixel circuit.

### SUMMARY

When an unintended capacitance variation occurs with respect to sub-pixels providing light of a same color, visibility may be deteriorated due to occurrence of mura on a display screen, for example. Therefore, an appropriate capacitance is desired to be formed for sub-pixels to improve the display quality of the display device.

Embodiments provide a display device and an electronic device comprising a display device in which a capacitance is appropriately designed, such that a risk that mura or the like will occur can be reduced, thereby improving visibility and having improved display quality.

In accordance with an embodiment of the disclosure, a display device includes: pixels each including sub-pixels; and a first direct current (DC) line and a second DC line, where each of the sub-pixels includes: a light emitting element; and a sub-pixel circuit electrically connected to the light emitting element, the sub-pixel circuit being electrically connected to the first DC line and the second DC line, where the sub-pixel circuit includes: a first transistor, where a gate electrode of the first transistor is electrically connected to a first node and one electrode of the first transistor is electrically connected to a second node; a storage capacitor connected between the first node and the second node; a first hold capacitor forming a first hold capacitance between the second node and the first DC line; and a second hold capacitor forming a second hold capacitance between the second node and the second DC line, and where sub-pixels which provides light of a same color among the sub-pixels, a sum of the first hold capacitance is equal to a sum of the second hold capacitance.

In an embodiment, the first DC line may be applied with a first DC voltage, and the second DC line may be applied with a second DC voltage.

In an embodiment, the display device may further include a reference power line, an initialization power line, a first power line, and a second power line, which are electrically connected to the sub-pixel circuit. In such an embodiment, the reference power line may provide a reference power voltage to the sub-pixel circuit. In such an embodiment, the initialization power line may provide an initialization power voltage to the sub-pixel circuit. In such an embodiment, the first power line may provide a first power voltage to the sub-pixel circuit. In such an embodiment, the second power line may provide a second power voltage to the light emitting element.

In an embodiment, the first power voltage or the reference power voltage may be applied to the first DC line.

In an embodiment, one selected from the reference power voltage, the initialization power voltage, the first power voltage, and the second power voltage may be applied to the second DC line.

In an embodiment, the sub-pixel circuit may further include: a second transistor, where one electrode of the second transistor is connected to the first node; a third transistor, where one electrode of the third transistor is connected to the first node and another electrode of the third transistor is electrically connected to the reference power line; a fourth transistor, where one electrode of the fourth transistor is electrically connected to an anode electrode of the light emitting element and another electrode is electrically connected to the initialization power line; a fifth transistor, where one electrode of the fifth transistor is electrically connected to another electrode of the first transistor and another electrode of the fifth transistor is electrically connected to the first power line; and a sixth transistor, where one electrode of the sixth transistor is electrically connected to the second node and another electrode of the sixth transistor is electrically connected to the anode electrode. In such an embodiment, the second power line may be electrically connected to a cathode electrode of the light emitting element.

In an embodiment, the display device may include a base layer, a first lower conductive layer on the base layer, an active layer on the first lower conductive layer, a gate conductive layer on the active layer, a first interlayer conductive layer on the gate conductive layer, and a second interlayer conductive layer on the first interlayer conductive layer. In such an embodiment, the active layer may include a first active layer defining a semiconductor portion of the first transistor. In such an embodiment, the gate conductive layer may include a first gate conductive layer defining the gate electrode of the first transistor. In such an embodiment, the first interlayer conductive layer may include a first first interlayer conductive layer (hereinafter, will be referred to as “(1-1)th interlayer conductive layer”) electrically connected to the first active layer, the (1-1)th interlayer conductive layer being electrically connected to the second node. In such an embodiment, the second interlayer conductive layer may include a first second interlayer conductive layer (hereinafter, will be referred to as “(2-1)th interlayer conductive layer”) forming at least a portion of the first DC line and a second second interlayer conductive layer (hereinafter, will be referred to as “(2-2)th interlayer conductive layer”) forming at least a portion of the second DC line. In such an embodiment, a storage capacitance may be formed between the first node and the second node in a storage capacitance area. In such an embodiment, the storage capacitance area may include a first storage capacitance area in which the first gate conductive layer and the (1-1)th interlayer conductive layer overlap each other.

In an embodiment, the (2-2)th interlayer conductive layer and the (1-1)th interlayer conductive layer may overlap each other in a plan view such that the second hold capacitance is formed.

In an embodiment, the gate conductive layer may include a second gate conductive layer electrically connected to the first gate conductive layer. In such an embodiment, the (1-1)th interlayer conductive layer may be electrically connected to the first active layer through a contact member disposed in an opening defined by the first gate conductive layer and the second gate conductive layer. In such an embodiment, the lower conductive layer may include a first first lower conductive layer (hereinafter, will be referred to as “(1-1)th lower conductive layer”). In such an embodiment, the first gate conductive layer may extend in a way such that at least a portion of the first gate conductive layer does not overlap the first active layer. In such an embodiment, the storage capacitance area may include a second storage capacitance area and a third storage capacitance area. In such an embodiment, in the second storage capacitance area, a portion of the first gate conductive layer, which does not overlap the first active layer, and the (1-1)th lower conductive layer may overlap each other. In such an embodiment, in the third storage capacitance area, the second gate conductive layer and the (1-1)th lower conductive layer may overlap each other.

In an embodiment, in a first hold capacitance area, the first hold capacitance may be formed between the first DC line and the second node. In such an embodiment, the first hold capacitance area may include a first first hold capacitance area (hereinafter, will be referred to as “(1-1)th hold capacitance area”). In such an embodiment, in the (1-1)th hold capacitance area, the (2-1)th interlayer conductive layer and the (1-1)th interlayer conductive layer may overlap each other.

In an embodiment, the first hold capacitance area may include a second first hold capacitance area (hereinafter, will be referred to as “(1-2)th hold capacitance area”) and a third first hold capacitance area (hereinafter, will be referred to as “(1-3)th hold capacitance area”). In such an embodiment, the first lower conductive layer may include a second first conductive layer (hereinafter, will be referred to as “(1-2)th lower conductive layer”) to which the first DC voltage is applied. In such an embodiment, the first interlayer conductive layer may include a second first interlayer conductive layer (hereinafter, will be referred to as “(1-2)th interlayer conductive layer”) electrically connected to the (1-2)th lower conductive layer. In such an embodiment, the active layer may include a second active layer of which at least a portion overlaps the (1-1)th lower conductive layer in a plan view. In such an embodiment, the second active layer may be electrically connected to the (1-2)th interlayer conductive layer. In such an embodiment, the first DC line may be formed by at least a portion of each of the (1-2)th lower conductive layer, the (1-2)th interlayer conductive layer, the second active layer, and the (2-1)th interlayer conductive layer. In such an embodiment, in the (1-2)th hold capacitance area, the second active layer and the (1-1)th lower conductive layer may overlap each other. In such an embodiment, in the (1-3)th hold capacitance area, the second active layer and the (1-1)th interlayer conductive layer may overlap each other. In such an embodiment, the (1-1)th hold capacitance area, the (1-2)th hold capacitance area, and the (1-3)th hold capacitance area may overlap one another.

In an embodiment, at least a portion of the first DC line and at least a portion of the second DC line may be disposed in a same layer.

In an embodiment, the display device may include a second lower conductive layer disposed between the first lower conductive layer and the active layer. In such an embodiment, the first lower conductive layer may include a first lower conductive portion. In such an embodiment, the second lower conductive layer may include a second lower conductive portion. In such an embodiment, the first lower conductive portion may define at least a portion of the first DC line. In such an embodiment, the second lower conductive portion may be electrically connected to the (1-1)th interlayer conductive layer. In such an embodiment, the first lower conductive portion and the second lower conductive portion may overlap each other in a plan view such the first hold capacitance is formed therebetween.

In an embodiment, the storage capacitance area may include a second storage capacitance area. In such an embodiment, in the second storage capacitance area, a portion of the first gate conductive layer, which does not overlap the first active layer, may overlap the second lower conductive portion.

In an embodiment, the pixels may be arranged along a first direction. In such an embodiment, the second DC line may extend in a second direction different from the first direction to overlap the sub-pixels.

In an embodiment, the pixels may include a first pixel, a second pixel, a third pixel, and a fourth pixel, which are arranged in the first direction. In such an embodiment, the second DC line may include second DC lines overlapping the sub-pixels of each of the first pixel, the second pixel, the third pixel, and the fourth pixel. In such an embodiment, a first portion of the second DC lines may be applied with the reference power voltage, a second portion of the second DC lines may be applied with the initialization power voltage, a third portion of the second DC lines may be applied with the first power voltage, and a fourth portion of the second DC lines may be applied with the second power voltage.

In an embodiment, shapes of the second DC line in sub-pixels which provide lights of different colors among the sub-pixels may be different from each other such that values of the second hold capacitance are different from each other with respect to the sub-pixels which provide the lights of the different colors among the sub-pixels.

In an embodiment, the sub-pixels may include a first sub-pixel, a second sub-pixel, and a third sub-pixel. In such an embodiment, the first DC line may include first DC lines overlapping each of the first sub-pixel, the second sub-pixel, and the third sub-pixel. In such an embodiment, the first DC lines in each of the first sub-pixel, the second sub-pixel, and the third sub-pixel may include a first protrusion portion. In such an embodiment, the first DC lines in the second sub-pixel in the first sub-pixel and the second sub-pixel may include a second protrusion portion. In such an embodiment, the first DC line in the second sub-pixel may include a three protrusion portion.

In an embodiment, at least a portion of the first DC line, which is in a same layer as the second DC line, may have an island shape.

In an embodiment, the sub-pixels may include a first sub-pixel and a second sub-pixel. In such an embodiment, the pixels may include a first pixel and a second pixel. In such an embodiment, the second DC line of the first sub-pixel in the first pixel and the second DC line of the first sub-pixel in the second pixel may have a same shape as each other. In such an embodiment, the second DC line of the second sub-pixel in the first pixel and the second DC line of the second sub-pixel in the second pixel may have a same shape as each other.

In accordance with an embodiment of the disclosure, an electronic device includes: a processor which provides input image data; a display device which displays an image based on the input image data, the display device including sub-pixel areas; and a power supply configured to supply power to the display device. In such an embodiment, the display device includes: pixels each including sub-pixels; and a first direct current (DC) line and a second DC line. In such an embodiment, each of the sub-pixels may include: a light emitting element; and a sub-pixel circuit electrically connected to the light emitting element, where the sub-pixel circuit is electrically connected to the first DC line and the second DC line. In such an embodiment, the sub-pixel circuit includes: a first transistor, where a gate electrode of the first transistor is electrically connected to a first node and one electrode of the first transistor is electrically connected to a second node; a storage capacitor connected between the first node and the second node; a first hold capacitor forming a first hold capacitance between the second node and the first DC line; and a second hold capacitor forming a second hold capacitance between the second node and the second DC line. In such an embodiment, in sub-pixels which provide light of a same color among the sub-pixels, a sum of the first hold capacitance is equal to a sum of the second hold capacitance.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic diagram illustrating a display device in accordance with embodiments of the disclosure.

FIG. 2 is a schematic circuit diagram illustrating an embodiment of a sub-pixel included in the display device shown in FIG. 1.

FIG. 3 is a schematic plan view illustrating a display device in accordance with an embodiment of the disclosure.

FIGS. 4 and 5 are schematic sectional views illustrating a display device in accordance with an embodiment of the disclosure.

FIG. 6 is a schematic sectional view illustrating a pixel circuit layer in accordance with an embodiment of the disclosure.

FIG. 7 is a schematic sectional view illustrating a display device in accordance with an embodiment of the disclosure.

FIGS. 8 and 9 are schematic plan views illustrating sub-pixels and lines penetrating the sub-pixels in accordance with an embodiment of the disclosure.

FIGS. 10 and 11 are schematic plan views illustrating a structure of sub-pixels and lines penetrating the sub-pixels on a plane in accordance with an embodiment of the disclosure.

FIG. 12 is a schematic sectional view illustrating a pixel circuit layer in accordance with an embodiment of the disclosure.

FIG. 13 is a schematic sectional view illustrating a display device in accordance with an embodiment of the disclosure.

FIG. 14 is a schematic block diagram illustrating an electronic device including a display device in accordance with an embodiment.

FIG. 15 is a schematic diagram illustrating an embodiment where the electronic device of FIG. 14 is implemented as a smartphone.

FIG. 16 is a schematic diagram illustrating an embodiment where the electronic device of FIG. 14 is implemented as a tablet computer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout..

Some embodiments are described in the accompanying drawings in relation to functional blocks, units, and/or modules. Those skilled in the art will understand that these blocks, units, and/or modules are physically implemented by logic circuits, individual components, microprocessors, hard wire circuits, memory elements, line connection, and other electronic circuits. This may be formed by using semiconductor-based manufacturing techniques or other manufacturing techniques. In the case of blocks, units, and/or modules implemented by microprocessors or other similar hardware, the units, and/or modules are programmed and controlled by using software, to perform various functions discussed in the disclosure, and may be selectively driven by firmware and/or software. In addition, each block, each unit, and/or each module may be implemented by dedicated hardware or by a combination dedicated hardware to perform some functions of the block, the unit, and/or the module and a processor (e.g., one or more programmed microprocessors and associated circuitry) to perform other functions of the block, the unit, and/or the module. In some embodiments, the blocks, the units, and/or the modules may be physically separated into two or more individual blocks, two or more individual units, and/or two or more individual modules without departing from the scope of the disclosure. Also, in some embodiments, the blocks, the units, and/or the modules may be physically separated into more complex blocks, more complex units, and/or more complex modules without departing from the scope of the disclosure.

In the drawing figures, dimensions may be exaggerated for clarity of illustration. It will be understood that when an element is referred to as being “between” two elements, it can be the only element between the two elements, or one or more intervening elements may also be present.

The term “connection” between two components may include both electrical connection and physical connection, but the disclosure is not necessarily limited thereto. For example, the term “connection” used based on circuit diagrams may mean electrical connection.

It will be understood that when an element is referred to as being “on” another element, it can be directly on the other element or intervening elements may be present therebetween. In contrast, when an element is referred to as being “directly on”another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or. ” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Meanwhile, the disclosure is not limited to embodiments disclosed below, and may be implemented in various forms. Each embodiment disclosed below may be independently embodied or be combined with at least another embodiment prior to being embodied.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

For clarity of explanation of the disclosure, some elements not directly related to features of the disclosure may be omitted in the drawings. In addition, the size, proportion, and the like of some elements in the drawings may be slightly exaggerated. It should be noted that a same reference numerals are used to designate a same or similar elements throughout the drawings, and a repetitive description thereof will be omitted.

The disclosure generally relates to a display device and an electronic device including a display device. Hereinafter, a display device and an electronic device comprising a display device in accordance with an embodiment of the disclosure will be described with reference to the accompanying drawings.

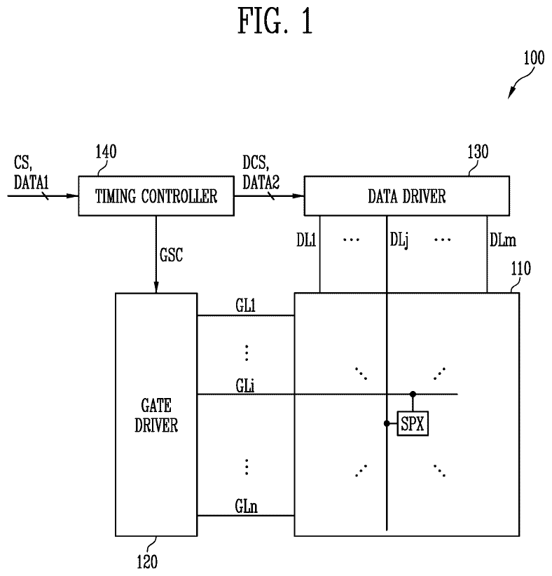

FIG. 1 is a schematic diagram illustrating a display device in accordance with embodiments of the disclosure.

Referring to FIG. 1, an embodiment of the display device 100 may include a display panel 110, a gate driver 120 (or scan driver), a data driver 130 (or source driver), and a timing controller 140 (or processor).

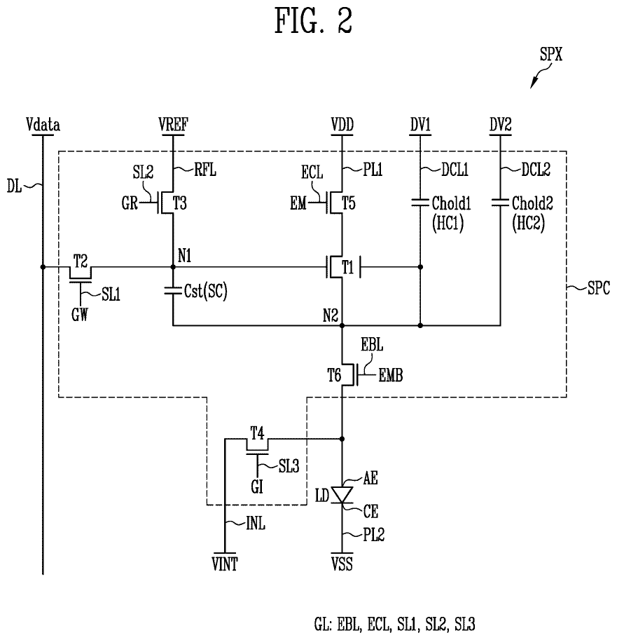

The display device 100 may be configured to emit light. The display device 100 may include a light source. In an embodiment, for example, the display device 100 may include an organic light emitting element, an inorganic light emitting element (e.g., an inorganic light emitting element having a size of nanometer scale to micrometer scale), or the like. However, the disclosure is not necessarily limited thereto. Hereinafter, an embodiment in which the display device 100 includes, as a light source, a light emitting element LD (see FIG. 2) including an organic light emitting element will be mainly described.

The display panel 110 may display an image. The display panel 110 may include gate lines GL1 to GLn (n is a positive integer greater than 1), data lines SL1 to DLm (m is a positive integer greater than 1), and sub-pixels SPX.

The sub-pixels SPX may be disposed in areas (e.g., pixel areas) defined by the gate lines GL1 to GLn and the data lines DL1 to DLm.

The sub-pixels SPX may be connected to the gate lines GL1 to GLn and the data lines DL1 to DLm. In an embodiment, for example, a sub-pixel disposed on an i-th pixel row and a j-th pixel row may be connected to an ith gate line Gli and a j-th data line DLj. Here, i is a positive integer smaller than or equal to n, and j is a positive integer smaller than or equal to m.

The sub-pixel SPX may emit light with a luminance corresponding to a data signal provided through a corresponding data line among the data lines DL1 to DLm in response to a gate signal provided through a corresponding gate line among the gate lines GL1 to GLn.

Various power voltages may be provided to the display panel 110. In an embodiment, for example, power voltages may be provided to the display panel 110 from a power supply such as a power management integrated circuit (PMIC). The power voltages may be driving voltages used for an operation of the sub-pixel SPX. The power voltage will be described later with reference to FIG. 2.

The gate driver 120 may generate a gate signal (e.g., a gate signal having a turn-on voltage level at which a transistor is turned on), based on a gate control signal GCS (or scan control signal), and sequentially provide the gate signal to the gate lines GL1 to GLn. The gate control signal GCS may include a start signal, a clock signal, or the like, and be provided from the timing controller 140. In an embodiment, for example, the gate driver 120 may include a shift register (or stage) which sequentially outputs a gate signal in the form of a pulse corresponding to the start signal, using the clock signal.

The data driver 130 may generate data signals, based on image data DATA2 and a data control signal DCS, which are provided from the timing controller 140, and provide the data signals to the display panel 110 (or the sub-pixels SPX). The data control signal DCS is a signal for controlling an operation of the data driver 130, and may include a horizontal start signal, a data clock signal, or the like. In an embodiment, for example, the data driver 130 may include a shift register which generates a sampling signal by shifting the horizontal start signal in synchronization with the data clock signal, a latch which latches input image data DATA1 in response to the sampling signal, a digital-to-analog converter (or decoder) which converts the latched image data (e.g., data in a digital form) into a data signal in an analog form, and a buffer (or amplifier) which outputs the data signal to the data lines DL1 to DLm.

The timing controller 140 may receive the input image data DATA1 and a control signal CS from an external device (e.g., a host processor, a main processor, or an application processor), generate the gate control signal GCS and the data control signal DCS, based on the control signal CS, and generate the image data DATA2 by converting the input image data DATA1. In an embodiment, for example, the timing controller 140 may convert the input image data in an RGB format into the image data DATA2 in an RGBG, which corresponds to a pixel arrangement in the display panel 110.

At least one selected from the gate driver 120, the data driver 130, and the timing controller 140 may be formed in the display panel 110, or be implemented as an integrated circuit (IC) to be connected to the display panel 110 through a flexible circuit board. In addition, at least two selected from the gate driver 120, the data driver 130, and the timing controller 140 may be implemented into one IC.

FIG. 2 is a schematic circuit diagram illustrating an embodiment of the sub-pixel included in the display device shown in FIG. 1.

Referring to FIGS. 1 and 2, in an embodiment, a sub-pixel SPX may be electrically connected to a gate line GL and a data line DL. The gate line GL may be a corresponding one of the gate lines GL1 to GLn shown in FIG. 1, and the data line DL may be a corresponding one of the data lines DL1 to DLm shown in FIG. 1. The gate line GL may include a first scan line SL1, a second scan line SL2, a third scan line SL3, a first emission control line ECL, and a second emission control line EBL. Driving signals may be applied to the gate line GL and the data line DL. A first scan signal GW may be applied to the first scan line SL1, a second scan signal GR may be applied to the second scan line SL2, and a third scan signal GI may be applied to the third scan line SL3. A first emission control signal EM may be applied to the first emission control line ECL, a second emission control signal EMB may be applied to the second emission control line EBL, and a data signal Vdata (or data voltage) may be applied to the data line DL.

In an embodiment, the sub-pixel SPX may be further connected to a first power line PL1, a second power line PL2, a reference power line RFL, and an initialization power line INL. Power voltages may be applied to the first power line PL1, the second power line PL2, the reference power line RFL, and the initialization power line INL. A first power voltage VDD may be applied, a second power voltage VSS may be applied to the second power line PL2, a reference power voltage VREF may be applied to the reference power line RFL, and an initialization power voltage VINT may be applied to the initialization power line INL. In an embodiment, for example, the first power line PL1 may provide the first power voltage VDD to a sub-pixel circuit SPC, the second power line PL2 may provide the second power voltage VSS to a light emitting element LD, the reference power line RFL may provide the reference power voltage VREF to the sub-pixel circuit SPC, and the initialization power line INL may provide the initialization power voltage VINT to the sub-pixel circuit SPC. A voltage level of the first power voltage VDD may be higher than a voltage level of the second power voltage VSS. A voltage level of the reference power voltage VREF may be equal to or different from the voltage level of the first power voltage VDD. A voltage level of the initialization power voltage VINT may be lower than the voltage level of the first power voltage VDD and be higher than the voltage level of the second power voltage VDD. However, the power voltages are not limited to, and the voltage levels of the power voltages may be variously changed according to product specifications.

In an embodiment, the sub-pixel SPX may include the sub-pixel circuit SPC and the light emitting element LD.

The sub-pixel circuit SPC may include a first transistor T1 (or driving transistor), a second transistor T2, and a storage capacitor Cst. Also, the sub-pixel circuit SPC may further include a third transistor T3, a fourth transistor T4, a fifth transistor T5, a sixth transistor T6, a first hold capacitor Chold1, and a second hold capacitor Chold2.

The first transistor T1 may be electrically connected between the first power line PL1 and a second node N2. In an embodiment, for example, a first electrode of the first transistor T1 may be connected to the first power line PL1 via the fifth transistor T5, and a second electrode of the first transistor T1 may be connected to the second node N2. A gate electrode of the first transistor T1 may be connected to a first node N1. Also, the first transistor T1 may further include a lower electrode (or a second gate electrode) corresponding to the gate electrode, and the lower electrode may be connected to the second node N2. The first transistor T1 may supply a driving current to the light emitting element LD or control an amount of driving current flowing through the light emitting element LD from the first power line PL1. In an embodiment, for example, the first transistor T1 may supply, to the light emitting element LD, a driving current corresponding to a voltage of the first node N1.

The second transistor T2 may be electrically connected between the data line DL and the first node N1. A gate electrode of the second transistor T2 may be connected to the first scan line SL1. The second transistor T2 may be turned on in response to the first scan signal GW of the first scan line SL1. When the second transistor T2 is turned on, the data signal Vdata of the data line DL may be transferred to the first node N1.

The third transistor T3 may be electrically connected between the reference power line RFL and the first node N1. A gate electrode of the third transistor T3 may be connected to the second scan line SL2. The third transistor T3 may be turned on in response to the second scan signal GR of the second scan line SL2. When the third transistor T3 is turned on, the reference power voltage VREF may be transferred to the first node N1.

The fourth transistor T4 may be electrically connected between an anode electrode AE of the light emitting element LD and the initialization power line INL. A gate electrode of the fourth transistor T4 may be connected to the third scan line SL3. The fourth transistor T4 may be turned on in response to the third scan signal GI of the third scan line SL3. When the fourth transistor T4 is turned on, the initialization power voltage VINT may be transferred to the anode electrode AE of the light emitting element LD.

The fifth transistor T5 may be electrically connected between the first power line PL1 and the first transistor T1. A gate electrode of the fifth transistor T5 may be connected to the first emission control line ECL. The fifth transistor T5 may be turned on in response to the first emission control signal EM of the first emission control line ECL.

The sixth transistor T6 may be electrically connected between the second node N2 and the anode electrode AE of the light emitting element LD. A gate electrode of the sixth transistor T6 may be connected to the second emission control line EBL. The sixth transistor T6 may be turned on in response to the second emission control signal EMB of the second emission control line EBL.

When the fifth transistor T5 and the sixth transistor T6 are turned on, a current path, through which a driving current can flow, may be formed from the first power line PL1 to the second power line PL2 via the sub-pixel circuit SPC and the light emitting element LD.

The storage capacitor Cst may be formed or electrically connected between the first node N1 and the second node N2. A voltage corresponding to the data voltage Vdata may be stored in the storage capacitor Cst. In an embodiment, for example, one storage capacitance SC (e.g., voltage information corresponding to the storage capacitance SC) may be stored (or formed) in the storage capacitor Cst.

The first hold capacitor Chold1 may be formed or electrically connected between a first direct current (DC) line DCL1 and the second node N2. The first hold capacitor Chold1 may stabilize a voltage of the second node N2. In an embodiment, for example, a first hold capacitance HC1 (e.g., voltage information corresponding to the first hold capacitance HC1) may be formed in the first hold capacitor Chold1.

A first DC voltage DV1 may be applied to the first DC line DCL1. In some embodiments, the first power voltage VDD or the reference power voltage VREF may be applied.

In an embodiment where the first power voltage VDD is applied to the first DC line DCL1, the first DC line DCL1 may be electrically connected to the first power line PL1 or be integrally formed with the first power line PL1.

In an embodiment where the reference power voltage VREF is applied to the first DC line DCL1, the first DC line DCL1 may be electrically connected to the initialization power line INL or be integrally formed with the initialization power line INL.

The second hold capacitor Chold2 may be formed or electrically connected between a second DC line DCL2 and the second node N2. The second hold capacitor Chold2 may stabilize the voltage of the second node N2. In an embodiment, for example, a second hold capacitance HC2 (e.g., voltage information corresponding to the second hold capacitance HC2) may be formed in the second hold capacitor Chold2.

The first and second hold capacitors Chold1 and Chold2 may be electrically connected to a same node, i.e., the second node N2.

A second DC voltage DV2 may be applied to the second DC line DCL2. In some embodiments, one of the reference power voltage VREF, the initialization power voltage VINT, the first power voltage VDD, and the second power voltage VSS may be applied to the second DC line DCL2.

In an embodiment where the reference power voltage VREF is applied to the second DC line DCL2, the second DC line DCL2 may be electrically connected to the reference power line RFL or be integrally formed with the reference power line RFL.

In an embodiment where the initialization power voltage VINT is applied to the second DC line DCL2, the second DC line DCL2 may be electrically connected to the initialization power line INL or be integrally formed with the initialization power line INL.

In an embodiment where the first power voltage VDD is applied to the second DC line DCL2, the second DC line DCL2 may be electrically connected to the first power line PL1 or be integrally formed with the first power line PL1.

In an embodiment where the second power voltage VSS is applied to the second DC line DCL2, the second DC line DCL2 may be electrically connected to the second power line PL2 or be integrally formed with the second power line PL2.

The anode electrode AE of the light emitting element LD may be electrically connected to the sub-pixel circuit SPC, and a cathode electrode CE of the light emitting element LD may be electrically connected to the second power line PL2. The light emitting element LD may be electrically connected between the sixth transistor T6 and the second power line PL2. In an embodiment, for example, the light emitting element LD may be connected in a forward direction between the second node N2 and the second power line PL2. When a driving current is supplied from the first transistor T1, the light emitting element LD may emit light with a luminance corresponding to the driving current.

In an embodiment, the first to sixth transistors T1 to T6 may be implemented with an N-type transistor, but the disclosure is not limited thereto. In another embodiment, for example, at least one selected from the first to sixth transistors T1 to T6 may be replaced with a P-type transistor. According to a type of each transistor, voltage levels of driving signals for controlling an operation of the transistor may be set.

In an embodiment, at least one selected from the first to sixth transistors T1 to T6 may include an oxide semiconductor. In an embodiment, for example, at least one transistor including the first transistor T1 may be an oxide semiconductor transistor including an oxide semiconductor.

In an embodiment, the sub-pixel circuit of the display device 100 may further include the second hold capacitor Chold2, and accordingly, a sufficient capacitance can be provided or formed at a portion connected to the second node N2.

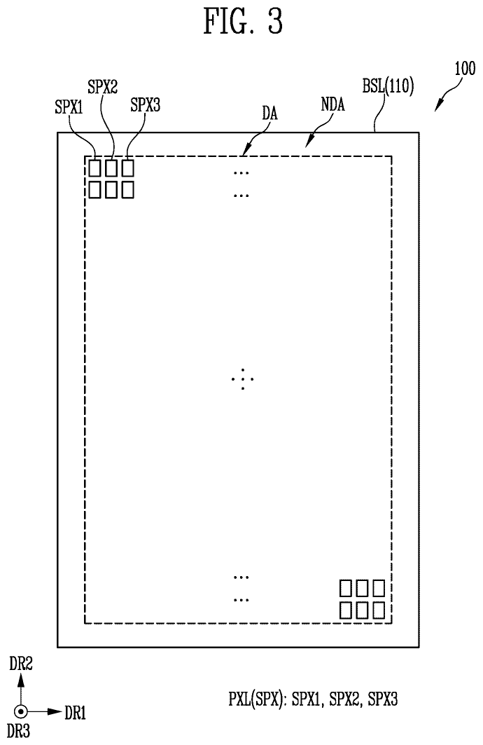

In such an embodiment, the display device 100 may include conductive portions for forming the first and second hold capacitors Chold1 and Chold2, and accordingly, a capacitance can be uniformly formed with respect to sub-pixels SPX that provide light of a same color. This will be described later with reference to drawings from FIG. 3.

Sectional and planar structures of a display device 100 in accordance with an embodiment of the disclosure will be described with reference to FIGS. 3 to 13. In FIGS. 3 to 13, any repetitive detailed descriptions of the same or like elements as those described above will be omitted or simplified.

FIG. 3 is a schematic plan view illustrating a display device in accordance with an embodiment of the disclosure.

Referring to FIG. 3, an embodiment of the display device 100 may include a base layer BSL and a display panel 110 including pixels PXL disposed on the base layer BSL. The display device 100 may further include a driving circuit (e.g., a scan driver and a data driver) for driving the pixels PXL, lines, and pads.

The display device 100 (or the base layer BSL) may include a display area DA and a non-display area NDA. The non-display area NDA may mean an area except the display area DA. The non-display area NDA may surround at least a portion of the display area DA.

The base layer BSL may form or provide a base surface of the display device 100. The base layer BSL may be a lower substrate for disposing layers forming or constituting the display device 100. The base layer BSL may be a rigid or flexible substrate or film. In an embodiment, for example, the base layer BSL may include a glass material. Alternatively, the base layer BSL may include a silicon material. Alternatively, the base layer BSL may include polyimide. However, the disclosure is not limited thereto.

In the disclosure, a plane is a plane extending in a first direction DR1 and a second direction DR2, and may be defined with respect to a plane on which the base layer BSL is disposed. In some embodiments, a third direction DR3 may be a thickness direction of the base layer BSL. The third direction DR3 may cross or be perpendicular to the first direction DR1 and the second direction DR2. The third direction DR3 may be a light emission direction of the display device 100.

The display area DA may mean an area in which the pixels PXL are disposed. The non-display area NDA may mean an area in which the pixels PXL are not disposed. The driving circuit, the lines, and the pads, which are connected to the pixels PXL of the display area DA, may be disposed in the non-display area NDA.

In an embodiment, the pixels PXL (or sub-pixels SPX) may be arranged according to a stripe arrangement structure, a PENTILE™ arrangement structure, or the like. However, the disclosure is not limited thereto, and various embodiments may be applied in the disclosure.

In an embodiment, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form or collectively define one pixel unit capable of emitting lights of various colors.

Each of the first sub-pixel SPX1, the second sub-pixel SPX2, and the third sub-pixel SPX3 may emit light of a predetermined color, e.g., one of primary colors.

In an embodiment, for example, the first sub-pixel SPX1 may be a red pixel that emits light of red (e.g., the first color), the second sub-pixel SPX2 may be a green pixel that emits light of green (e.g., the second color), and the third sub-pixel SPX3 may be a blue pixel that emits light of blue (e.g., the third color). The red pixel may provide light in a wavelength band of about 600 nanometers (nm) to about 750 nm. The green pixel may provide light in a wavelength band of about 480 nm to about 560 nm. The blue pixel may provide light in a wavelength band of about 370 nm to about 460 nm.

In an embodiment, a number of second sub-pixels SPX2 may be greater than a number of first sub-pixels SPXL1 and a number of third sub-pixels SPXL3. However, the color, kind, and/or number of first, second, and third sub-pixels SPX1, SPX2, and SPX3 constituting each pixel unit are not limited to a specific example.

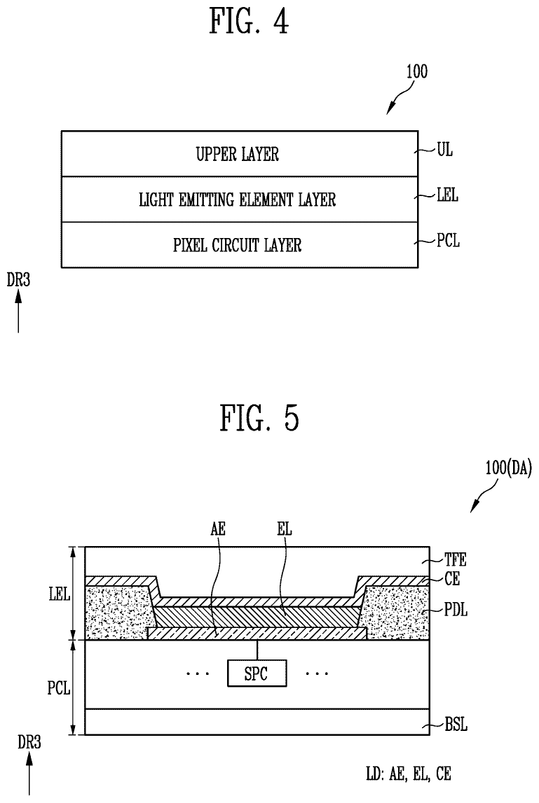

FIGS. 4 and 5 are schematic sectional views illustrating a display device 100 in accordance with an embodiment of the disclosure. FIG. 5 illustrates a portion of the display device 100 in a display area DA.

Referring to FIGS. 4 and 5, an embodiment of the display device 100 may include a pixel circuit layer PCL and light emitting element layer LEL. The display device 100 may further include an upper layer UL on the light emitting element layer LEL.

The pixel circuit layer PCL may include a base layer BSL. The pixel circuit layer PCL may be a layer including a sub-pixel circuit SPC. The pixel circuit layer PCL may be a backplane layer. The sub-pixel circuit SPC may be disposed or formed on the base layer BSL, and be configured to drive a light emitting element LD. The pixel circuit layer PCL may include conductive layers and insulating layers, and the conductive layers may form the sub-pixel circuit SPC. The sub-pixel circuit SPC may include circuit elements. The circuit elements may include a driving transistor, and include additional transistors and capacitors.

The light emitting element layer LEL may be disposed on the pixel circuit layer PCL. The light emitting element layer LEL may include the light emitting element LD. The light emitting element layer LEL may further include a pixel defining layer PDL and an encapsulation layer TFE.

The light emitting element LD may be electrically connected to the sub-pixel circuit SPC. In some embodiments, the light emitting element LD may include an organic light emitting diode (OLED) including an organic material. Alternatively, in some embodiments, the light emitting element LD may include an inorganic organic light emitting diode including an inorganic material. However, the disclosure is not limited thereto. In this specification, for convenience of description, an embodiment in which the light emitting element LD is the OLED will be mainly described.

The light emitting element LD may include an anode electrode AE, a light emitting structure EL, and a cathode electrode CE. In some embodiments, the light emitting structure EL may be disposed in an area defined by the pixel defining layer PDL. The pixel defining layer PDL may be adjacent to the periphery of the light emitting structure EL. One surface of the light emitting structure EL may be electrically connected to the anode electrode AE, and an opposite surface of the light emitting structure EL may be electrically connected to the cathode electrode CE. The anode electrode AE and the cathode electrode CE may include various conductive materials.

The light emitting structure EL may include a plurality of layers. In an embodiment, for example, the light emitting structure EL may include a plurality of light emitting structures including a hole transport unit, a light emitting layer (or light generation layer), and an electron transport unit. Each of the layers forming the light emitting structure may include one organic material. In some embodiments, each of the layers forming the light emitting structure may further include an inorganic a metal-containing compound, an inorganic material such as a quantum dot, or the like.

The hole transport unit may include a multi-layer structure having a plurality of layers including different materials. In an example, the hole transport unit may a hole injection layer and a hole transport layer. In some embodiments, the hole transport unit may further include a light emitting auxiliary layer, an electron bocking layer, or the like.

The light emitting layer may include a material capable of emitting light of a color. The light emitting layer may include a host and a dopant. The host of the light emitting layer is a light emitting material capable of capturing carriers (electrons and holes) for generating light, and may induce excitons to be efficiently generated. The dopant of the light emitting layer may include a phosphorescent dopant and a fluorescent dopant. In some embodiments, examples of the dopant are not particularly limited. In some embodiments, the dopant may include an organic material. The dopant may also include a metal complex and the like.

The electron transport unit may have a multi-layer structure including a plurality of layers including different materials, respectively. The electron transport unit may include an electron injection layer and an electron transport layer. In some embodiments, the electron transport unit may further include an electron buffer layer, a hole blocking layer, and the like.

The pixel defining layer PDL may be disposed on the pixel circuit layer PCL, to define a position at which the light emitting structure EL is arranged. The pixel defining layer PDL may include an organic material or an inorganic material. In an embodiment, for example, the pixel defining layer PDL may include a plurality of layers each including an inorganic material. However, the disclosure is not limited thereto.

The encapsulation layer TFE may be disposed over the light emitting element LD (e.g., the cathode electrode CE). The encapsulation layer TFE may compensate a step difference generated by the light emitting element LD and the pixel defining layer PDL. The encapsulation layer TFE may a plurality of insulating layers covering the light emitting element LD. In some embodiments, the encapsulation layer TFE may include an inorganic layer and an organic layer. In an embodiment, for example, the encapsulation layer TFE may have a structure in which a first inorganic layer, an organic layer, and a second inorganic layer are sequentially disposed. However, the disclosure is not limited thereto. In some embodiments, the encapsulation layer TFE may be a thin film encapsulation layer.

The upper layer UL may be disposed on the light emitting element layer. The upper layer UL may include various layers, such as a cover window, which allow light to be transmitted therethrough. In some embodiments, the upper layer UL may include a color filter, include a lens array layer, and include a polarizing layer. However, the disclosure is not limited to a specific example.

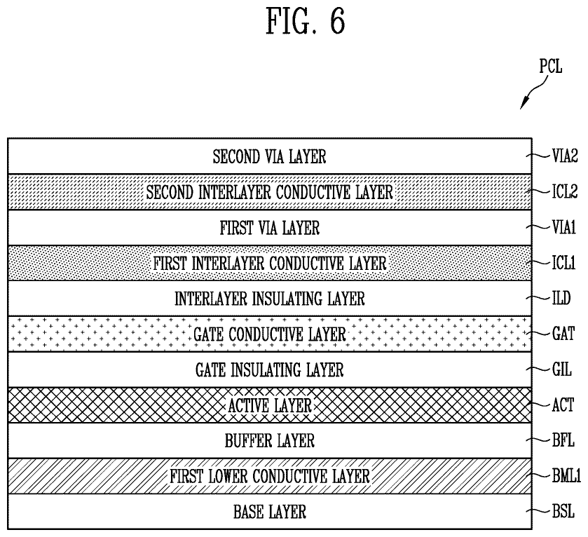

A structure of a sub-pixel circuit SPC and lines, which are included in a display device 100 in accordance with an embodiment of the disclosure, will be described with reference to FIGS. 6 to 11. In FIGS. 6 to 11, any repetitive detailed descriptions of the same or like elements as those described above will be omitted or simplified.

First, a stacked structure defined in a pixel circuit layer PCL in accordance with an embodiment of the disclosure will be described. FIG. 6 is a schematic sectional view illustrating a pixel circuit layer in accordance with an embodiment of the disclosure. In drawings from FIG. 6 to FIG. 13, a same layer (e.g., a layer formed or patterned through a same process) may be indicated by a same hatching.

Referring to FIG. 6, the pixel circuit layer PCL may include conductive layers, insulating layers, or the like, which are disposed on a base layer BSL. In an embodiment, for example, the pixel circuit layer PCL may have a form in which at least a portion of each of the base layer BSL, a first lower conductive layer BML1, a buffer layer BFL, an active layer ACT, a gate insulating layer GIL, a gate conductive layer GAT, an interlayer insulating layer ILD, a first interlayer conductive layer ICL1, a first via layer VIA1, a second interlayer insulating layer ICL2, and a second via layer VIA2 is patterned in a structure in which the base layer BSL, the first lower conductive layer BML1, the buffer layer BFL, the active layer ACT, the gate insulating layer GIL, the gate conductive layer GAT, the interlayer insulating layer ILD, the first interlayer conductive layer ICL1, the first via layer VIA1, the second interlayer insulating layer ICL2, and the second via layer VIA2 are stacked.

The active layer ACT may be disposed on the buffer layer BFL. The active layer ACT may include a semiconductor. In an embodiment, for example, the active layer ACT may include at least one selected from poly-silicon, low temperature polycrystalline silicon (LTPS), amorphous silicon, and an oxide semiconductor. The active layer ACT may form or define a least a portion of transistors of the sub-pixel circuit SPC.

The first lower conductive layer BML1, the gate conductive layer GAT, the first interlayer conductive layer ICL1, and the second interlayer conductive layer ICL2 may include a conductive material, and each of the first lower conductive layer BML1, the gate conductive layer GAT, the first interlayer conductive layer ICL1, and the second interlayer conductive layer ICL2 may have a single-layer or multi-layer structure. At least portions of each of the first lower conductive layer BML1, the gate conductive layer GAT, the first interlayer conductive layer ICL1, and the second interlayer conductive layer ICL2 may be electrically connected to each other through a contact member CNP defined in at least one selected from the insulating layers, and form the sub-pixel circuit SPC and lines electrically connected to the sub-pixel circuit SPC or a light emitting element LD.

In the disclosure, a structure electrically connecting conductive layers disposed in different layers in the pixel circuit layer PCL may be referred to as a contact member CNP.

The buffer layer BFL, the gate insulating layer GIL, the interlayer insulating layer ILD, the first via layer VIA1, and the second via layer VIA2 may be disposed between at least some of the conductive layers forming the pixel circuit layer PCL, and each of the buffer layer BFL, the gate insulating layer GIL, the interlayer insulating layer ILD, the first via layer VIA1, and the second via layer VIA2 may include at least one selected from various insulative materials such as an inorganic material and organic material.

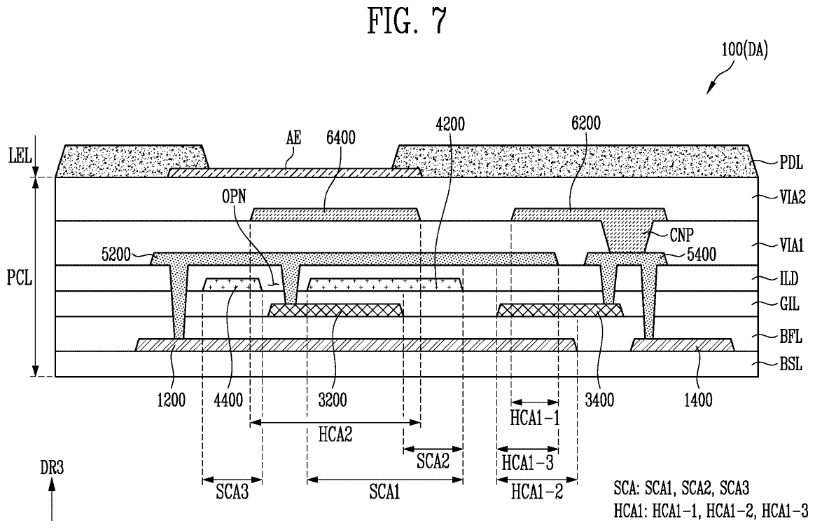

FIG. 7 is a schematic sectional view illustrating a display device in accordance with an embodiment of the disclosure. FIG. 7 illustrates a sub-pixel circuit SPC and at least some of lines electrically connected to the sub-pixel circuit SPC in a display area DA. For convenience of description, in FIG. 7, only a pixel defining layer PDL and an anode electrode AE are illustrated as a portion of a light emitting element layer LEL.

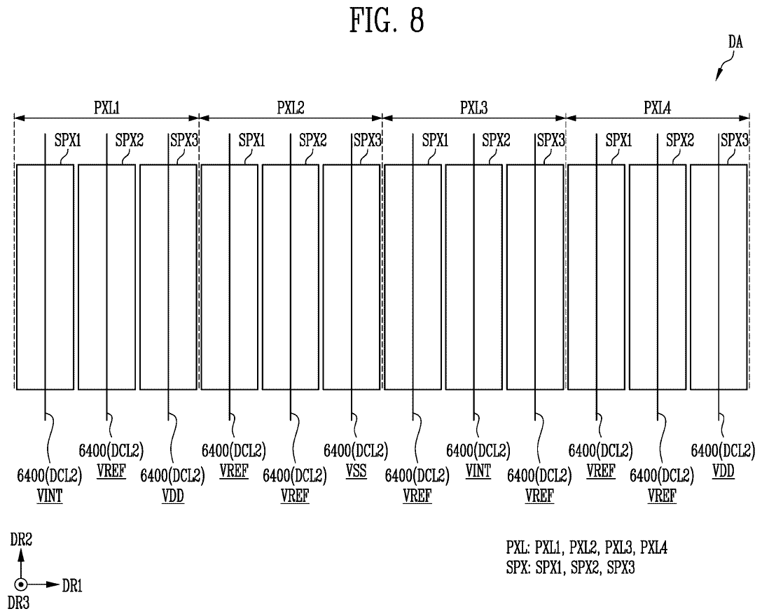

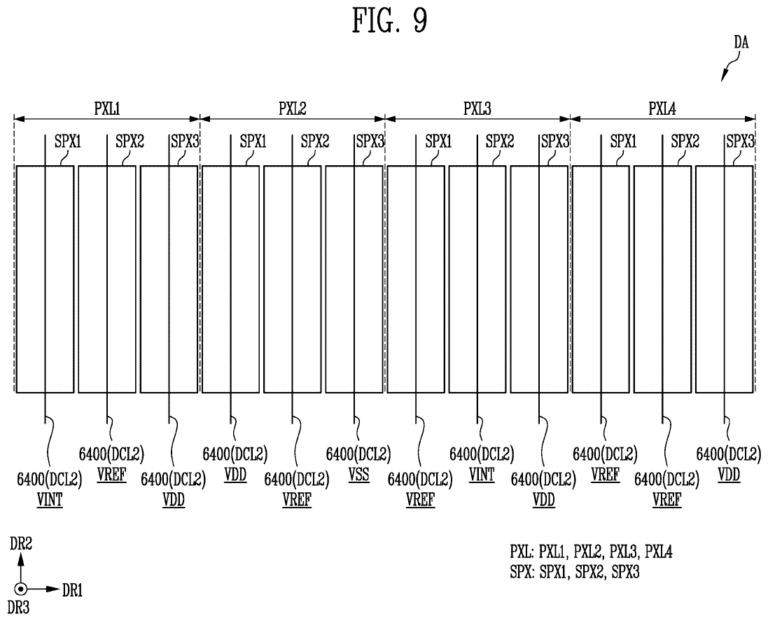

FIGS. 8 and 9 are schematic plan views illustrating sub-pixels and lines penetrating the sub-pixels in accordance with an embodiment of the disclosure. FIGS. 8 and 9 schematically illustrate pixels PXL adjacent to each other and lines penetrating each of sub-pixels SPX in a vertical direction. FIGS. 8 and 9 schematically illustrate a partial area in the display area DA.

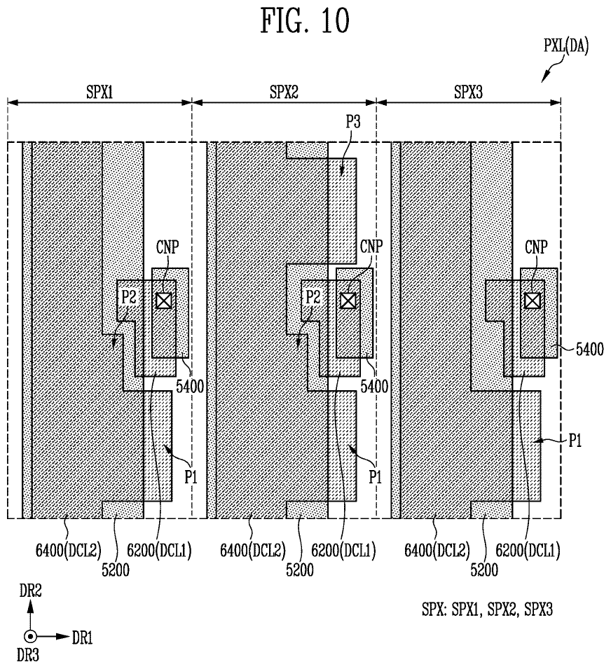

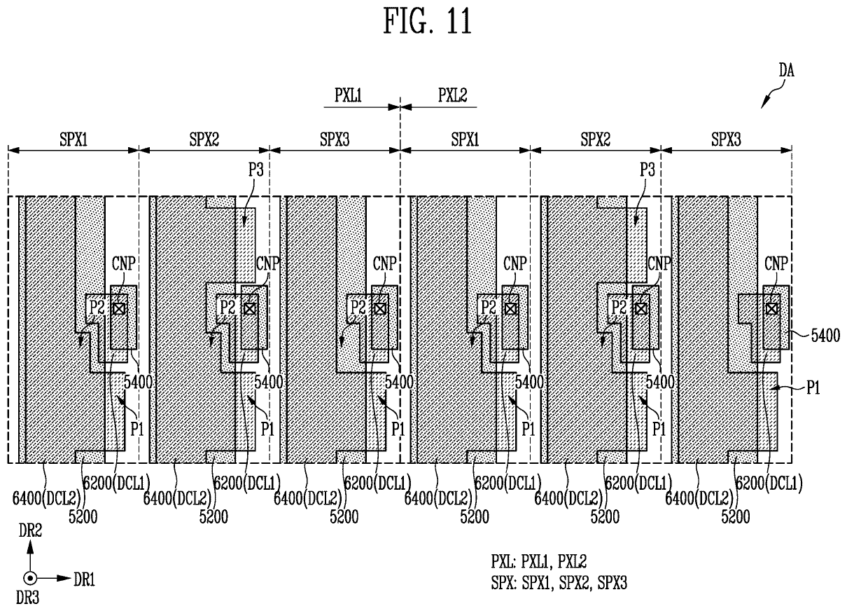

FIGS. 10 and 11 are schematic plan views illustrating a structure of sub-pixels and lines penetrating the sub-pixels on a plane in accordance with an embodiment of the disclosure. FIGS. 10 and 11 schematically illustrate the first and second interlayer conductive layers ICL1 and ICL2 described above. FIGS. 10 and 11 schematically illustrate a partial area in the display area DA. FIG. 10 schematically illustrate one pixel PXL in accordance with an embodiment of the disclosure, and FIG. 11 schematically illustrate pixels PXL adjacent to each other in accordance with an embodiment of the disclosure.

Referring to FIG. 7, at least a portion of each of the storage capacitor Cst, the first hold capacitor Chold1, and the second hold capacitor Chold2 may be formed or defined by conductive layers of the pixel circuit layer PCL.

The display device 100 may include a first first lower conductive layer (hereinafter, will be referred to as “(1-1)th lower conductive layer”) 1200 and a second first lower conductive layer (hereinafter, will be referred to as “(1-2)th lower conductive layer”) 1400, which are disposed on the base layer BSL. The (1-1)th lower conductive layer 1200 and the (1-2)th lower conductive layer 1400 may be formed by (or defined by portions of) the first lower conductive layer BML1, and be covered by the buffer layer BFL.

The display device 100 may include a first active layer 3200 and a second active layer 3400, which are disposed on the buffer layer BFL. The first active layer 3200 and the second active layer 3400 may be formed by (or defined by portions of) the active layer ACT, and be covered by the gate insulating layer GIL.

The display device 100 may include a first gate conductive layer 4200 and a second gate conductive layer 4400, each of which at least a portion is disposed on the gate insulating layer GIL. The first gate conductive layer 4200 and the second gate conductive layer 4400 may be formed by (or defined by portions of) the gate conductive layer GAT, and be covered by the interlayer insulating layer ILD.

The display device 100 may include a first first interlayer conductive layer (hereinafter, will be referred to as “(1-1)th interlayer conductive layer”) 5200 and a second first interlayer conductive layer (hereinafter, will be referred to as “(1-2)th interlayer conductive layer”) 5400, which are disposed on the interlayer insulating layer ILD. The (1-1)th interlayer conductive layer 5200 and the (1-2)th interlayer conductive layer 5400 may be formed by (or defined by portions of) the first interlayer conductive layer ICL1, and be covered by the first via layer VIA1.

The display device 100 may include a first second interlayer conductive layer (hereinafter, will be referred to as “(2-1)th interlayer conductive layer”) 6200 and a second second interlayer conductive layer (hereinafter, will be referred to as “(2-2)th interlayer conductive layer”) 6400, which are disposed on the first via layer VIA1. The (2-1)th interlayer conductive layer 6200 and the (2-2)th interlayer conductive layer 6400 may be formed by (or defined by portions of) the second interlayer conductive layer ICL2, and be covered by the second via layer VIA2.

In some embodiments, the first active layer 3200 may form or define a semiconductor portion of the first transistor T1 (e.g., the driving transistor).

In some embodiments, the first gate conductive layer 4200 and the second gate conductive layer 4400 may form or define at least a portion of the first node N1. The first gate conductive layer 4200 and the second gate conductive layer 4400 may form or define at least a portion of the gate electrode of the first transistor T1 (e.g., the driving transistor). The first gate conductive layer 4200 may overlap the first active layer 3200 in a plan view (or in the third direction DR3), and be electrically connected to the second gate conductive layer 4400. In an embodiment, for example, the first gate conductive layer 4200 and the second gate conductive layer 4400 may be integrated with each other, and the (1-1)the interlayer conductive layer 5200 and the first active layer 3200 may be electrically connected to each other through a contact member CNP formed or disposed in an opening OPN surrounded by (or defined through) the first gate conductive layer 4200 and the second gate conductive layer 4400.

In some embodiments, the (1-1)th interlayer conductive layer 5200 and the (1-1)th lower conductive layer 1200 may form or define at least a portion of the second node N2. In an embodiment, for example, the (1-1)th interlayer conductive layer 5200 may be electrically connected to the first active layer 3200 through a contact member CNP disposed through the gate insulating layer GIL and the interlayer insulating layer ILD, and the (1-1)th interlayer conductive layer 5200 and the (1-1)th lower conductive layer 1200 may be electrically connected to each other through a contact member CNP disposed through the gate insulating layer GIL, the interlayer insulating layer ILD, and the buffer layer BFL.

In some embodiments, the (1-2)th lower conductive layer 1400, the second active layer 3400, the (1-2)th interlayer conductive layer 5400, and the (2-1)th interlayer conductive layer 6200 may form or define at least a portion of the first DC line DCL1. In an embodiment, for example, the (1-2)th lower conductive layer 1400, the second active layer 3400, the (1-2)th interlayer conductive layer 5400, and the (2-1)th interlayer conductive layer 6200 may be electrically connected to each other through contact members CNP, and be applied with the first DC voltage DV1. In an embodiment, for example, the (1-2)th lower conductive layer 1400 may extend in one direction in the display area DA, and be provided with the first DC voltage DV1. The second active layer 3400, the (1-2)th interlayer conductive layer 5400, and the (2-1)th interlayer conductive layer 6200, which are electrically connected to the (1-2)th lower conductive layer 1400, may be provided with the first DC voltage DV1.

In some embodiments, the (2-2)th interlayer conductive layer 6400 may form at least a portion of the second DC line DCL2. For example, the (2-2)th interlayer conductive layer 6400 may be applied with the second DC voltage DV2.

In some embodiments, a conductive portion forming (or defining) the first node N1 and a conductive portion forming the second node N2 may form (or collectively define) the storage capacitor Cst, and form the storage capacitance SC.

In some embodiments, a storage capacitance area SCA, in which the storage capacitance SC is formed, may be formed (or defined) in the pixel circuit layer PCL. In some embodiments, the storage capacitance area SCA may include a first storage capacitance area SCA1, a second storage capacitance area SCA2, and a third storage capacitance area SCA3. Accordingly, the storage capacitor Cst in accordance with the embodiment of the disclosure may effectively form a sufficient storage capacitance SC.

In the first storage capacitance area SCA1, the (1-1)th interlayer conductive layer 5200 and the first gate conductive layer 4200 may overlap each other in the third direction DR3. In the disclosure, when two elements are referred to as overlapping each other, the two elements may overlap each other in the third direction DR3. In the storage capacitance area SCA1, at least a portion of the (1-1)th interlayer conductive layer 5200 and at least a portion of the first gate conductive layer 4200 may face each other, and form a storage capacitance SC.

In the second storage capacitance area SCA2, the first gate conductive layer 4200 and the (1-1)th lower conductive layer 1200 may overlap each other. In the second storage capacitance area SCA2, at least a portion of the first gate conductive layer 4200 and at least a portion of the (1-1)th lower conductive layer 1200 may face each other, and form a storage capacitance SC. In an embodiment, for example, the first gate conductive layer 4200 may extend in one direction such that at least a portion of the first gate conductive layer 4200 does not overlap the first active layer 3200 in a plan view. The at least a portion of the first gate conductive layer 4200, which does not overlap the first active layer 3200, may overlap at least a portion of the (1-1)th lower conductive layer 1200 disposed under the first active layer 3200, and the at least a portion of the first gate conductive layer 4200 and the at least a portion of the (1-1)th lower conductive layer 1200 may face each other.

In the third storage capacitance area SCA3, the second gate conductive layer 4400 and the (1-1)th interlayer conductive layer 5200 may overlap each other. In the third storage capacitance area SCA3, at least a portion of the second gate conductive layer 4400 and at least a portion of the (1-1)th interlayer conductive layer 5200 may face each other, and form a storage capacitance SC. In the third storage capacitance area SCA3, the second gate conductive layer 4400 and the (1-1)th lower conductive layer 1200 may overlap each other. In the third storage capacitance area SCA3, at least a portion of the second gate conductive layer 4400 and at least a portion of the (1-1)th interlayer conductive layer 5200 may face each other, and form a storage capacitance SC.

In some embodiments, the third storage capacitance area SCA3 may not overlap the first and second storage capacitance area SCA1 and SCA2. The first and second storage capacitance area SCA1 and SCA2 may overlap each other.

In some embodiments, a conductive portion forming (or defining) the second node N2 and a conductive portion forming the first DC line DCL1 may form a first hold capacitance HC1. Accordingly, the first hold capacitor Chold1 in accordance with an embodiment of the disclosure can form a sufficient first hold capacitance HC1.

In some embodiments, a first hold capacitance area HCA1 in which the first hold capacitance HC1 is formed may be formed (or defined) in the pixel circuit layer PCL. In some embodiments, the first hold capacitance area HCA1 may include a third first hold capacitance area (hereinafter, will be referred to as “(1-3)th hold capacitance area”) HCA1-3, a second first hold capacitance area (hereinafter, will be referred to as “(1-2)th hold capacitance area”) HCA1-2, and a first first hold capacitance area (hereinafter, will be referred to as “(1-1)th hold capacitance area”) HCA1-1.

In the (1-1)th hold capacitance area HCA1-1, the (1-1)th interlayer conductive layer 5200 and the (2-1)th interlayer conductive layer 6200 may overlap each other. In the (1-2)th hold capacitance area HCA1-2, at least a portion of the (1-1)th interlayer conductive layer 5200 and at least a portion of the (2-1)th interlayer conductive layer 6200 may face each other, and form a first hold capacitance HC1.

In the (1-2)th hold capacitance area HCA1-2, the second active layer 3400 and the (1-1)th lower conductive layer 1200 may overlap each other. In the (1-2)th hold capacitance area HCA1-2, at least a portion of the second active layer 3400 and at least a portion of the (1-1)th lower conductive layer 1200 may face each other, and form a first hold capacitance HC1.

In the (1-3)th hold capacitance area HCA1-3, the second active layer 3400 and the (1-1)th interlayer conductive layer 5200 may overlap each other. In the (1-3)th hold capacitance area HCA1-3, at least a portion of the second active layer 3400 and at least a portion of the (1-1)th interlayer conductive layer 5200 may face each other, and form a first hold capacitance HC1.

In some embodiments, the (1-1)th hold capacitance area HCA1-1, the (1-2)th hold capacitance are HCA1-2, and the (1-3)th hold capacitance area HCA1-3 may overlap one another.

In some embodiment, a conductive portion forming (or defining) the second node N2 and a conductive portion forming the second DC line DCL2 may form a second hold capacitance HC2.

In some embodiments, a second hold capacitance area HCA2 in which the second hold capacitance HC2 is formed may be formed (or defined) in the pixel circuit layer PCL.

In the second hold capacitance area HCA2, the (1-1)th interlayer conductive layer 5200 and the (2-2)th interlayer conductive layer 6400 may overlap each other. In the second hold capacitance area HCA2, at least a portion of the (1-1)th interlayer conductive layer 5200 and at least a portion of the (2-2)th interlayer conductive layer 6400 may face each other, and form a second hold capacitance HC2.

In some embodiments, at least a portion of the second DC line DCL2, which forms the second hold capacitance HC2, and at least a portion of the first DC line DCL1, which forms the first hold capacitance HC1, may be disposed in a same layer. In an embodiment, for example, the (2-1)th interlayer conductive layer 6200 and the (2-2)th interlayer conductive layer 6400 may be disposed in (or defined by) a same layer.

In some embodiments, the second hold capacitance area HCA2 may overlap the storage capacitance area SCA. In an embodiment, for example, the second hold capacitance area HCA2 may overlap each of the first to third storage capacitance areas SCA1 to SCA3.

In some embodiments, the (2-2)th interlayer conductive layer 6400 forming at least a portion of the second DC line DCL2 may be disposed on the (1-1)th interlayer conductive layer 5200 forming (or defining) at least a portion of the second node N2.

In an embodiment, as described above, the reference power voltage VREF, the initialization power voltage VINT, the first power voltage VDD, or the second power voltage VSS may be applied to the second DC line DCL2, and the (1-1)th interlayer conductive layer 5200 may form at least a portion of the second node N2. Thus, the second hold capacitance HC2 can be additionally secured, and the voltage of the second node N2 can be further stabilized.

In such an embodiment of the disclosure, since the (2-2)th interlayer conductive layer 6400 forming the second hold capacitance HC2 is disposed above the (1-1)th interlayer conductive layer 5200 extending relatively widely, the magnitude of the second hold capacitance HC2 can be efficiently adjusted using the area of the (2-2)th interlayer conductive layer 6400. In accordance with an embodiment of the disclosure, as the (1-1)th interlayer conductive layer 5200 extends relatively widely, the first to third storage capacitance areas SCA1 to SCA3 can be formed, and the second hold capacitance HC2 can be efficiently adjusted.

within such an embodiment, a sum of the first hold capacitance HC1 and a sum of the second hold capacitance HC2 with respect to sub-pixels SPX that provide light of a same color may be substantially the same as each other. This will be described with reference to FIGS. 8 to 11.

Referring to FIGS. 8 to 11, in an embodiment, pixels PXL may be arranged in the display area DA. The arrangement structure of the pixels PXL is not limited to a specific example. Hereinafter, for convenience of description, an embodiment in which the pixels PXL are arranged (e.g., sequentially arranged) along the first direction DR1 will be described in detail.

In some embodiments, a plurality of pixels PXL may be formed. In an embodiment, for example, the pixels PXL may include a first pixel PXL1, a second pixel PXL2, a third pixel PXL3, and a fourth pixel PXL4, which are disposed in a partial area of the display area DA.

In some embodiments, each of the pixels PXL (e.g., each of the first pixel PXL1, the second pixel PXL2, the third pixel PXL3, and the fourth pixel PXL4) may include sub-pixels SPX. Each of the pixels PXL (e.g., each of the first pixel PXL1, the second pixel PXL2, the third pixel PXL3, and the fourth pixel PXL4) may include first to third sub-pixels SPX.

In some embodiments, the pixels PX may be arranged (e.g., sequentially arrange) along the first direction DR1. In an embodiment, for example, the first pixel PXL1, the second pixel PXL2, the third pixel PXL3, and the fourth pixel PXL4 may be arranged (e.g., sequentially arranged) along the first direction DR1.

In some embodiments, the second dc line DCL2 may extend in a direction different from the direction in which the pixels PXL are sequentially arranged. The second DC line DCL2 may extend in the second direction DR2. The (2-2)th interlayer conductive layer 6400 forming (or defining) the second DC line DCL2 may extend in the second direction DR2.

In some embodiments, the second DC line DCL2 may extend along the second direction DR2 to penetrate (or overlap) each of the sub-pixels SPX.

In some embodiments, the second DC line DCL2 may be formed in plurality in the display area DA. In an embodiment, for example, the second DC line DCL2 may include second DC lines DCL2. Each of the second DC lines DCL2 may overlap each of separate sub-pixels (e.g., corresponding sub-pixels SPX).

In some embodiments, a single second DC line DCL2 may overlap one sub-pixel SPX in the one sub-pixel SPX. However, the disclosure is not limited thereto.

In some embodiments, as described above, the second DC line DCL2 may be a line to which the second DC voltage DV2 is applied, and be applied with the reference power voltage VREF, the initialization power voltage VINT, the first power voltage VDD, or the second power voltage VSS. In an embodiment, for example, the second DC line DCL2 may extend to overlap a corresponding sub-pixel SPX, and be applied with one of the reference power voltage VREF, the initialization power voltage VINT, the first power voltage VDD, and the second power voltage VSS.

In some embodiments, a first portion of the second DC lines DCL2 in the first to fourth pixels PXL1 to PXL4 may be provided with the reference power voltage VREF. A second portion of the second DC lines DCL2 in the first to fourth pixels PXL1 to PXL4 may be provided with the initialization power voltage VINT. A third portion of the second DC lines DCL2 in the first to fourth pixels PXL1 to PXL4 may be provided with the first power voltage VDD. A fourth portion of the second DC lines DCL2 in the first to fourth pixels PXL1 to PXL4 may be provided with the second power voltage VSS.

In an embodiment, for example, as shown in FIG. 8, a second DC line DCL2 (e.g., a (2-2)th interlayer conductive layer 6400) overlapping a first sub-pixel SPX1 of the first pixel PXL1 may be provided with the initialization power voltage VINT, a second DC line DCL2 (e.g., a (2-2)th interlayer conductive layer 6400) overlapping a second sub-pixel SPX2 of the first pixel PXL1 may be provided with the reference power voltage VREF, a second DC line DCL2 (e.g., a (2-2)th interlayer conductive layer 6400) overlapping a third sub-pixel SPX3 of the first pixel PXL1 may be provided with the first power voltage VDD, a second DC line DCL2 (e.g., a (2-2)th interlayer conductive layer 6400) overlapping a first sub-pixel SPX1 of the second pixel PXL2 may be provided with the reference power voltage VREF, a second DC line DCL2 (e.g., a (2-2)th interlayer conductive layer 6400) overlapping a second sub-pixel SPX2 of the second pixel PXL2 may be provided with the reference power voltage VREF, a second DC line DCL2 (e.g., a (2-2)th interlayer conductive layer 6400) overlapping a third sub-pixel SPX2 of the second pixel PXL2 may be provided with the second power voltage VSS, a second DC line DCL2 (e.g., a (2-2)th interlayer conductive layer 6400) overlapping a first sub-pixel SPX1 of the third pixel PXL3 may be provided with the reference power voltage VREF, a second DC line DCL2 (e.g., a (2-2)th interlayer conductive layer 6400) overlapping a second sub-pixel SPX2 of the third pixel PXL3 may be provided with the initialization power source VINT, a second DC line DCL2 (e.g., a (2-2)th interlayer conductive layer 6400) overlapping a third sub-pixel SPX3 of the third pixel PXL3 may be provided with the reference power voltage VREF, a second DC line DCL2 (e.g., a (2-2)th interlayer conductive layer 6400) overlapping a first sub-pixel SPX1 of the fourth pixel PXL4 may be provided with the reference power voltage VREF, a second DC line DCL2 (e.g., a (2-2)th interlayer conductive layer 6400) overlapping a second sub-pixel SPX2 of the fourth pixel PXL4 may be provided with the reference power voltage VREF, and a second DC line DCL2 (e.g., a (2-2)th interlayer conductive layer 6400) overlapping a third sub-pixel SPX3 of the fourth pixel PXL4 may be provided with the first power voltage VDD.

In another embodiment, for example, as shown in FIG. 9, the second DC line DCL2 (e.g., the (2-2)th interlayer conductive layer 6400) overlapping the first sub-pixel SPX1 of the first pixel PXL1 may be provided with the initialization power voltage VINT, the second DC line DCL2 (e.g., the (2-2)th interlayer conductive layer 6400) overlapping the second sub-pixel SPX2 of the first pixel PXL1 may be provided with the reference power voltage VREF, the second DC line DCL2 (e.g., the (2-2)th interlayer conductive layer 6400) overlapping the third sub-pixel SPX3 of the first pixel PXL1 may be provided with the first power voltage VDD, the second DC line DCL2 (e.g., the (2-2)th interlayer conductive layer 6400) overlapping the first sub-pixel SPX1 of the second pixel PXL2 may be provided with the first power voltage VDD, the second DC line DCL2 (e.g., the (2-2)th interlayer conductive layer 6400) overlapping the second sub-pixel SPX2 of the second pixel PXL2 may be provided with the reference power voltage VREF, the second DC line DCL2 (e.g., the (2-2)th interlayer conductive layer 6400) overlapping the third sub-pixel SPX2 of the second pixel PXL2 may be provided with the second power voltage VSS, the second DC line DCL2 (e.g., the (2-2)th interlayer conductive layer 6400) overlapping the first sub-pixel SPX1 of the third pixel PXL3 may be provided with the reference power voltage VREF, the second DC line DCL2 (e.g., the (2-2)th interlayer conductive layer 6400) overlapping the second sub-pixel SPX2 of the third pixel PXL3 may be provided with the initialization power source VINT, the second DC line DCL2 (e.g., the (2-2)th interlayer conductive layer 6400) overlapping the third sub-pixel SPX3 of the third pixel PXL3 may be provided with the first power voltage VDD, the second DC line DCL2 (e.g., the (2-2)th interlayer conductive layer 6400) overlapping the first sub-pixel SPX1 of the fourth pixel PXL4 may be provided with the reference power voltage VREF, the second DC line DCL2 (e.g., the (2-2)th interlayer conductive layer 6400) overlapping the second sub-pixel SPX2 of the fourth pixel PXL4 may be provided with the reference power voltage VREF, and the second DC line DCL2 (e.g., the (2-2)th interlayer conductive layer 6400) overlapping the third sub-pixel SPX3 of the fourth pixel PXL4 may be provided with the first power voltage VDD.

Accordingly, the second DC line DCL2 to be applied with the second DC voltage DV2 may be patterned to form the second hold capacitance HC2 in each of the sub-pixels SPX.

Referring to FIG. 10, magnitudes of second hold capacitances HC2 may be differently formed with respect to sub-pixels SPX that provide lights of different colors in one pixel PXL. Accordingly, magnitudes of second hold capacitances HC2 may be optimized with respect to sub-pixels SPX that provide lights of different colors.

Shapes of second DC lines DCL2 on a plane may be different in each of sub-pixels SPX that provide lights of different colors such that values of second hold capacitances HC2 are different from each other with respect to the sub-pixels SPX.

The (1-1)th interlayer conductive layer 5200 forming (or defining) at least a portion of the second node N2 may be disposed to extend in the second direction DR2 in each of the sub-pixels SPX.

In some embodiments, a second DC line DCL2 (e.g., a (2-2)th interlayer conductive layer 6400) overlapping a first sub-pixel SPX1 may roughly extend in the second direction DR2, and include first and second protrusion portions P1 and P2. Accordingly, the (1-1)th interlayer conductive layer 5200 and the first and second protrusion portions P1 and P2 may further form first and second overlapping areas in a plan view. Accordingly, the second DC line DCL2 including the first and second protrusion portions P1 and P2 may form a second hold capacitance HC2 corresponding to the first sub-pixel SPX1.

In some embodiments, a second DC line DCL2 (e.g., a (2-2)th interlayer conductive layer 6400) overlapping a second sub-pixel SPX2 may roughly extend in the second direction DR2, and include a first protrusion portion P1, a second protrusion portion P2, and a third protrusion portion P3. Accordingly, the (1-1)th interlayer conductive layer 5200 and the first to third protrusion portions P1 to P3 may further form or define first to third overlapping areas in a plan view. Accordingly, the second DC line DCL2 including the first to third protrusion portions P1 to P3 may form a second hold capacitance HC2 corresponding to the second sub-pixel SPX2.

In some embodiments, a second DC line DCL2 (e.g., a (2-2)th interlayer conductive layer 6400) overlapping a third sub-pixel SPX3 may roughly extend in the second direction DR2, and include a first protrusion portion P1. Accordingly, the (1-1)th interlayer conductive layer 5200 and the first protrusion portion P1 may further form a first overlapping area in a plan view. Accordingly, the second DC line DCL2 including the first protrusion portion P1 may form a second hold capacitance corresponding to the third sub-pixel SPX3.

In some embodiments, the first protrusion portion P1 may be a portion formed at a lower side of a (2-1)th interlayer conductive layer 6200, the second protrusion portion P2 may be a portion adjacent the (2-1)th interlayer conductive layer 6200 in a horizontal direction (e.g., the first direction DR1), and the third protrusion portion P3 may be a portion formed at an upper side of the (2-1)th interlayer conductive layer 6200.

That is, in accordance with an embodiment, shapes of the second DC lines DCL2 may be different from one another with respect to the first to third sub-pixels SPX1 to SPX3 such that the value of the second hold capacitance HC2 may be appropriately formed for each of the first to third sub-pixels SPX1 to SPX3.

In some embodiments, a (1-2)th interlayer conductive layer 5400 may be electrically connected to the (2-1)th interlayer conductive layer 6200 forming at least a portion of the first DC line DCL1 through a contact portion CNP in each of the sub-pixels SPX.

In some embodiments, at least a portion of the first DC line DCL1 disposed in a same layer as the second DC line DCL2 may have an island shape. In some embodiments, each of the (2-1)th interlayer conductive layer 6200 and the (1-2)th interlayer conductive layer 5400 may have an island shape. At least a portion of the (2-1)th interlayer conductive layer 6200 may overlap the (1-1)th interlayer conductive layer 5200 in a plan view, and accordingly, a first hold capacitance HC1 may be formed.

In accordance with an embodiment, a sum of the first hold capacitance C1 and a sum of the second hold capacitance C2 in each of the sub-pixels SPX may be defined. As described above, since shapes of second DC lines DCL2 are different from one another and values of second hold capacitances HC2 are different from one another with respect to sub-pixels SPX that provide light of different colors, the sum of the first hold capacitance HC1 and the sum of the second hold capacitance HC2 with respect to sub-pixels SPX that provide lights of different colors may be different from one another. Accordingly, sums of the first hold capacitance HC1 and the second hold capacitance HC2 may be optimized with respect to sub-pixels SPX that provide light of different colors.

Also, in accordance with an embodiment, sums of the first hold capacitance HC1 and the second hold capacitance HC2 may be substantially the same as each other (e.g., equal to each other) with respect to sub-pixels SPX that provide lights of different colors.

In an embodiment, for example, as described above, overlapping ranges between the (2-2)th interlayer conductive layer 6400 and the (1-1)th interlayer conductive layer 5200 are different from one another according to the shapes of the second DC lines DCL2, and therefore, values of the second hold capacitances HC2 may be differently formed according to the shapes of the second DC lines DCL2.

In some embodiments, second DC lines DCL2 (e.g., (2-2)th interlayer conductive layers 6400) may have a same shape with respect to sub-pixels SPX that provide light of a same color. Accordingly, second hold capacitances HC2 may be equally formed with respect to sub-pixels SPX providing light of a same color.

Accordingly, a risk that optical information will be distorted (e.g., a risk that a luminance will be distorted or a risk that a phenomenon such as mura will occur) due to a capacitance variation with respect to sub-pixels SPX that provide light of a same color can be reduced.

In an embodiment, for example, in each of the first sub-pixels SPX1 of the first and second pixels PXL1 and PXL2, each of the second DC lines DCL2 may include the first and second protrusion portions P1 and P2, and may not include the third protrusion portion P3. In each of the second sub-pixels SPX2 of the first and second pixels PXL1 and PXL2, each of the second DC lines DCL2 may include the first to third protrusion portions P1 to P3. In each of the third sub-pixels SPX3 of the first and second pixels PXL1 and PXL2, each of the second DC lines DCL2 may include the first protrusion portion, and may not include the second and third protrusion portions P2 and P3.

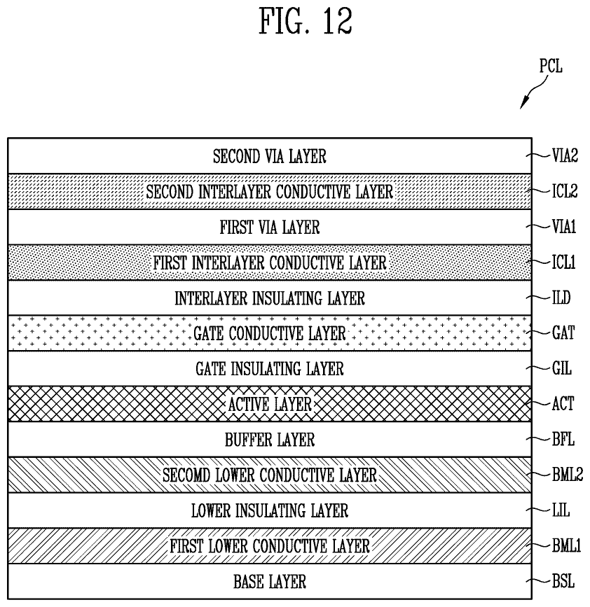

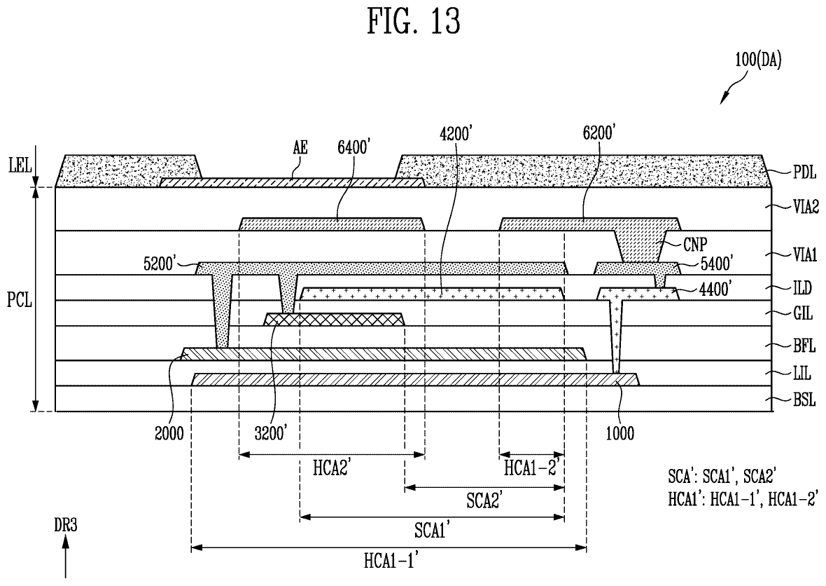

Hereinafter, a structure of a sub-pixel circuit SPC and lines, included in a display device 100 in accordance with an embodiment of the disclosure will be described with reference to FIGS. 12 and 13. In FIGS. 12 and 13, any repetitive detailed descriptions of the same or like elements as those described above will be omitted or simplified.

The display device 100 in accordance with an embodiment shown in FIGS. 12 and 13 is substantially the same as the display device 100 in accordance with the above-described embodiment, except that the display device 100 further include a second lower conductive layer BML2 and a lower insulating layer LIL, and a portion of the second lower conductive layer BML2 forms at least a portion of the first hold capacitor Chold1.

FIG. 12 is a schematic sectional view illustrating a pixel circuit layer in accordance with an embodiment of the disclosure.

Referring to FIG. 12, the pixel circuit layer PCL in accordance with an embodiment of the disclosure may further include a second lower conductive layer BML2 and a lower insulating layer LIL.

The lower insulating layer LIL may be disposed between the first lower conductive layer BML1 and the second lower conductive layer BML2. The second lower conductive layer BML2 may be disposed on the lower insulating layer LIL, and be covered by the buffer layer BFL.

FIG. 13 is a schematic sectional view illustrating a display device in accordance with an embodiment of the disclosure. FIG. 13 illustrates a sub-pixel circuit SPC, at least some of lines electrically connected to the sub-pixel circuit SPC, and the like in a display area DA. For convenience of description, in FIG. 13, only a pixel defining layer PDL and an anode electrode AE are illustrated as a portion of a light emitting element layer LEL.

Referring to FIG. 13, at least a portion of each of the storage capacitor Cst, the first hold capacitor Chold1, and the second hold capacitor Chold2 may be formed or defined by conductive layers of the pixel circuit layer PCL.

The display device 100 may include a first lower conductive portion 1000 disposed on the base layer BSL. The first lower conductive portion 1000 may be formed (or defined by portions of) by the first lower conductive layer BML1, and be covered by the lower insulating layer LIL.

The display device 100 may include a second lower conductive portion 2000 disposed on the lower insulating layer LIL. The second lower conductive portion 2000 may be formed (or defined by portions of) by the second lower conductive layer BML2, and be covered by the buffer layer BFL.

The display device 100 may include a first active layer 3200′ disposed on the buffer layer BFL. The first active layer 3200′ may be formed by (or defined by portions of) the active layer ACT, and be covered by the gate insulating layer GIL.

The display device 100 may include a first gate conductive layer 4200′ and a second gate conductive layer 4400', each of which at least a portion is disposed on the gate insulating layer GIL. The first gate conductive layer 4200′ and the second gate conductive layer 4400′ may be formed by (or defined by portions of) the gate conductive layer GAT, and be covered by the interlayer insulating layer ILD.

The display device 100 may include a (1-1)th interlayer conductive layer 5200′ and a (1-2)th interlayer conductive layer 5400′, which are disposed on the interlayer insulating layer ILD. The (1-1)th interlayer conductive layer 5200′ and the (1-2)th interlayer conductive layer 5400′ may be formed by (or defined by portions of) the first interlayer conductive layer ICL1, and be covered by the first via layer VIA1.

The display device 100 may include a (2-1)th interlayer conductive layer 6200′ and a (2-2)th interlayer conductive layer 6400′, which are disposed on the first via layer VIA1. The (2-1)th interlayer conductive layer 6200′ and the (2-2)th interlayer conductive layer 6400′ may be formed by (or defined by portions of) the second interlayer conductive layer ICL2, and be covered by the second via layer VIA2.

In some embodiments, the first active layer 3200′ may form a semiconductor portion of the first transistor T1 (e.g., the driving transistor).

In some embodiments, the first gate conductive layer 4200′ may form at least a portion of the first node N1. The first gate conductive layer 4200′ may form at least a portion of the gate electrode of the first transistor T1 (e.g., the driving transistor). The first gate conductive layer 4200′ may overlap the first active layer 3200′ in a plan view.

In some embodiments, the (1-1)th interlayer conductive layer 5200′ and the second lower conductive portion 2000 may form at least a portion of the second node N2. In an embodiment, for example, the (1-1)th interlayer conductive layer 5200′ may be electrically connected to the first active layer 3200′ through a contact member CNP penetrating or disposed through the gate insulating layer GIL and the interlayer insulating layer ILD, and the (1-1)th interlayer conductive layer 5200′ and the second lower conductive portion 2000 may be electrically connected to each other through a contact member CNP penetrating the gate insulating layer GIL, the interlayer insulating layer ILD, and the buffer layer BFL.

In some embodiments, the first lower conductive portion 1000, the second gate conductive layer 4400′, the (1-2)th interlayer conductive layer 5400′, and the (2-1)th interlayer conductive layer 6200′ may form at least a portion of the first DC line DCL1.

In an embodiment, for example, the first lower conductive portion 1000, the second gate conductive layer 4400′, the (1-2)th interlayer conductive layer 5400′, and the (2-1)th interlayer conductive layer 6200′ may be electrically connected to each other through contact members CNP, and be applied with the first DC voltage DV1. In an embodiment, for example, the first lower conductive portion 1000 may extend in one direction in the display area DA, and be provided with the first DC voltage DV1. The second gate conductive layer 4400′, the (1-2)th interlayer conductive layer 5400′, and the (2-1)th interlayer conductive layer 6200′, which are electrically connected to the first lower conductive portion 1000, may be provided with the first DC voltage DV1.

In some embodiments, the (2-2)th interlayer conductive layer 6400′ may form at least a portion of the second DC line DCL2. In an embodiment, for example, the (2-2)th interlayer conductive layer 6400′ may be applied with the second DC voltage DV2.

In some embodiments, a conductive portion forming the first node N1 and a conductive portion forming the second node N2 may form (or collectively define) the storage capacitor Cst, and form the storage capacitance SC.

In some embodiments, a storage capacitance area SCA′ in which a storage capacitance SC is formed may be formed (or defined) in the pixel circuit layer PCL. In some embodiments, the storage capacitance area SCA′ may include a first storage capacitance area SCA1′ and a second storage capacitance area SCA2′.

In the first storage capacitance area SCA1′, the (1-1)th interlayer conductive layer 5200′ and the first gate conductive layer 4200′ may overlap each other. In the first storage capacitance area SCA1′, at least a portion of the (1-1)th interlayer conductive layer 5200′ and at least a portion of the first gate conductive layer 4200′ may face each other, and form a storage capacitance SC.

In the second storage capacitance area SCA2′, the second lower conductive portion 2000 and the first gate conductive layer 4200′ may overlap each other. In the second storage capacitance area SCA2′, at least a portion of the second lower conductive portion 200 and at least a portion of the first gate conductive layer 4200′ may face each other, and form a storage capacitance SC.

In some embodiments, a conductive portion forming the second node N2 and a conductive portion forming the first DC line DCL1 may form a first hold capacitance HC1.

In some embodiments, a first holed capacitance area HCA1′ in which a first hold capacitance HC1 is formed may be formed (or defined) in the pixel circuit layer PCL. In some embodiments, the first hold capacitance area HCA1′ may include a (1-1)th hold capacitance area HCA1-1′ and a (1-2)th hold capacitance area HCA1-2′.

In the (1-1)th hold capacitance area HCA1-1′, the first lower conductive portion 1000 and the second lower conductive portion 2000 may overlap each other. In the (1-1)th hold capacitance area HCA1-1′, at least a portion of the first lower conductive portion 1000 and at least a portion of the second lower conductive portion 2000 may face each other, and form a first hold capacitance HC1.

In the (1-2)th hold capacitance area HCA1-2′, the (1-1)th interlayer conductive layer 5200′ and the (2-1)th interlayer conductive layer 6200′ may overlap each other. In the (1-2)th hold capacitance area HCA1-2′, at least a portion of the (1-1)th interlayer conductive layer 5200′ and at least a portion of the (2-1)th interlayer conductive layer 6200′ may face each other, and form a first hold capacitance HC1.

In some embodiments, the (1-1)th hold capacitance area HCA1-1′ and the (1-2)th hold capacitance area HCA1-2′ may overlap each other.

In some embodiments, a conductive portion forming the second node N2 and a conductive portion forming the second DC line DCL2 may form a second hold capacitance HC2.

In some embodiments, a second hold capacitance area HCA2′ in which a second hold capacitance HC2 is formed may be formed (or defined) in the pixel circuit layer PCL.

In the second hold capacitance area HCA2′, the (1-1)th interlayer conductive layer 5200′ and the (2-2)th interlayer conductive layer 6400′ may overlap each other. In the second hold capacitance area HCA2′, at least a portion of the (1-1)th interlayer conductive layer 5200′ and at least a portion of the (2-2)th interlayer conductive layer 6400′ may face each other, and form a second hold capacitance HC2.

In some embodiments, the second hold capacitance area HCA2′ may overlap the storage capacitance area SCA′ and the first hold capacitance area HCA1′. In an embodiment, for example, the second hold capacitance area HCA2′ may overlap each of the first and second storage capacitance areas SCA1′ and SCA2′, and overlap the (1-1)th hold capacitance area HCA1-1′.

In such an embodiment, as described above, the reference power voltage VREF, the initialization power voltage VINT, the first power voltage VDD, or the second power voltage VSS may be applied to the second DC line DCL2, and the (1-1)th interlayer conductive layer 5200′ may form at least a portion of the second node N2. Thus, the second hold capacitance HC2 can be additionally secured, the voltage of the second node N2 can be further stabilized, and the second hold capacitance HC2 can be efficiently adjusted.

In such an embodiment of the disclosure, sums of the first hold capacitance HC1 and the second hold capacitance HC2 may be substantially the same as each other with respect to sub-pixels SPX that provides light of a same color, and accordingly, a risk that optical information will be distorted (e.g., a risk that a luminance will be distorted or a risk that a phenomenon such as mura will occur) due to a capacitance variation with respect to sub-pixels SPX providing light of a same color may be reduced.

Hereinafter, an electronic device 1000 including the display device DD in accordance with an embodiment will be described.

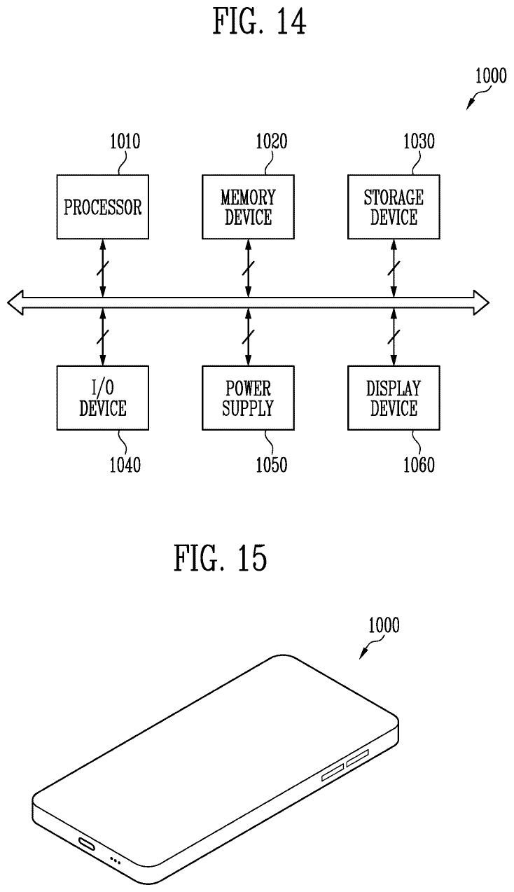

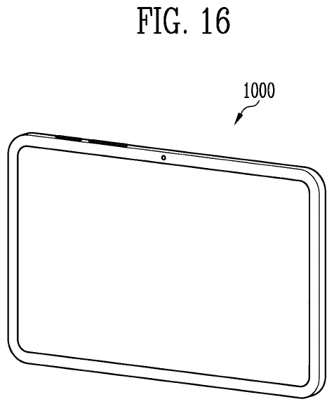

FIG. 14 is a schematic block diagram illustrating an electronic device 1000 including a display device in accordance with an embodiment. FIG. 15 is a schematic diagram illustrating an embodiment where the electronic device 1000 of FIG. 14 is implemented as a smartphone. FIG. 16 is a schematic diagram illustrating an embodiment where the electronic device 1000 of FIG. 14 is implemented as a tablet computer.

Referring to FIGS. 14 to 16, an embodiment of the electronic device 1000 may include a processor 1010, a memory device 1020, a storage device 1030, an input/output (I/O) device 1040, a power supply 1050, and a display device 1060. The display device 1060 may be the display device 100 of FIG. 1. The electronic device 1000 may further include various ports for communication with a video card, a sound card, a memory card, a USB device, or other systems. In an embodiment, as illustrated in FIG. 15, the electronic device 1000 may be implemented as a smartphone. In an embodiment, as illustrated in FIG. 16, the electronic device 1000 may be implemented as a tablet computer. However, the aforementioned examples are illustrative, and the electronic device 1000 is not necessarily limited to the aforementioned examples. In an embodiment, for example, the electronic device 1000 may be implemented as a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a micro-processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. In an embodiment, for example, the memory device 1020 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, etc.

The storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. In an embodiment, for example, the power supply 1050 may be a power management integrated circuit (PMIC). In an embodiment, the power supply 1050 may supply power to the display device 1060.

The display device 1060 may display an image corresponding to visual information of the electronic device 1000. The display device 1060 may be connected to other components through the buses or other communication links.

In embodiments of a display device and an electronic device including a display device, a capacitance is appropriately designed, such that a risk that mura or the like will occur can be reduced, thereby improving visibility and having improved display quality.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
pixels each including sub-pixels; and
a first direct current line, and a second direct current line,
wherein each of the sub-pixels includes:
a light emitting element; and
a sub-pixel circuit electrically connected to the light emitting element, wherein the sub-pixel circuit is electrically connected to the first direct current line and the second direct current line,
wherein the sub-pixel circuit includes:
a first transistor, wherein a gate electrode of the first transistor is electrically connected to a first node and one electrode of the first transistor is electrically connected to a second node;
a storage capacitor connected between the first node and the second node;
a first hold capacitor forming a first hold capacitance between the second node and the first direct current line; and
a second hold capacitor forming a second hold capacitance between the second node and the second direct current line, and
wherein, in sub-pixels which provide light of a same color among the sub-pixels, a sum of the first hold capacitance is equal to a sum of the second hold capacitance.

2. The display device of claim 1, wherein the first direct current line is applied with a first direct current voltage, and
the second direct current line is applied with a second direct current voltage.

3. The display device of claim 2, further comprising a reference power line, an initialization power line, a first power line, and a second power line, which are electrically connected to the sub-pixel circuit,
wherein the reference power line provides a reference power voltage to the sub-pixel circuit,
wherein the initialization power line provides an initialization power voltage to the sub-pixel circuit,
wherein the first power line provides a first power voltage to the sub-pixel circuit, and
wherein the second power line provides a second power voltage to the light emitting element.

4. The display device of claim 3, wherein the first power voltage or the reference power voltage is applied to the first direct current line.

5. The display device of claim 3, wherein one selected from the reference power voltage, the initialization power voltage, the first power voltage, and the second power voltage is applied to the second direct current line.

6. The display device of claim 5, wherein the sub-pixel circuit further includes:
a second transistor, wherein one electrode of the second transistor is connected to the first node;
a third transistor, wherein one electrode of the third transistor is connected to the first node and another electrode of the third transistor is electrically connected to the reference power line;
a fourth transistor, wherein one electrode of the fourth transistor is electrically connected to an anode electrode of the light emitting element and another electrode is electrically connected to the initialization power line;
a fifth transistor, wherein one electrode of the fifth transistor is electrically connected to another electrode of the first transistor and another electrode of the fifth transistor is electrically connected to the first power line; and
a sixth transistor, wherein one electrode of the sixth transistor is electrically connected to the second node and another electrode of the sixth transistor is electrically connected to the anode electrode, and
wherein the second power line is electrically connected to a cathode electrode of the light emitting element.

7. The display device of claim 3, comprising a base layer, a first lower conductive layer on the base layer, an active layer on the first lower conductive layer, a gate conductive layer on the active layer, a first interlayer conductive layer on the gate conductive layer, and a second interlayer conductive layer on the first interlayer conductive layer,
wherein the active layer includes a first active layer defining a semiconductor portion of the first transistor,
wherein the gate conductive layer includes a first gate conductive layer defining the gate electrode of the first transistor,
wherein the first interlayer conductive layer includes a first first interlayer conductive layer electrically connected to the first active layer, and the first first interlayer conductive layer is electrically connected to the second node,
wherein the second interlayer conductive layer includes a first second interlayer conductive layer defining at least a portion of the first direct current line and a second second interlayer conductive layer defining at least a portion of the second direct current line,
wherein a storage capacitance is formed between the first node and the second node in a storage capacitance area, and
wherein the storage capacitance area includes a first storage capacitance area in which the first gate conductive layer and the first first interlayer conductive layer overlap each other.

8. The display device of claim 7, wherein the second second interlayer conductive layer and the first first interlayer conductive layer overlap each other in a plan view such that the second hold capacitance is formed therebetween.

9. The display device of claim 8, wherein the gate conductive layer includes a second gate conductive layer electrically connected to the first gate conductive layer,
wherein the first first interlayer conductive layer is electrically connected to the first active layer through a contact member disposed in an opening defined by the first gate conductive layer and the second gate conductive layer,
wherein the lower conductive layer includes a first first lower conductive layer,
wherein the first gate conductive layer extends in a way such that at least a portion of the first gate conductive layer does not overlap the first active layer,
wherein the storage capacitance area includes a second storage capacitance area and a third storage capacitance area,
wherein, in the second storage capacitance area, a portion of the first gate conductive layer, which does not overlap the first active layer, and the first first lower conductive layer overlap each other, and
wherein, in the third storage capacitance area, the second gate conductive layer and the first first lower conductive layer overlap each other.

10. The display device of claim 9, wherein, in a first hold capacitance area, the first hold capacitance is formed between the first direct current line and the second node,
wherein the first hold capacitance area includes a first first hold capacitance area, and
wherein, in the first first hold capacitance area, the first second interlayer conductive layer and the first first interlayer conductive layer overlap each other.

11. The display device of claim 10, wherein the first hold capacitance area includes a second first hold capacitance area and a third first hold capacitance area,
wherein the first lower conductive layer includes a second first lower conductive layer to which the first direct current voltage is applied,
wherein the first interlayer conductive layer includes a second first interlayer conductive layer electrically connected to the second first lower conductive layer,
wherein the active layer includes a second active layer of which at least a portion overlaps the first first lower conductive layer in the plan view,
wherein the second active layer is electrically connected to the second first interlayer conductive layer,
wherein the first direct current line is defined by at least a portion of each of the second first lower conductive layer, the second first interlayer conductive layer, the second active layer, and the first second h interlayer conductive layer,
wherein, in the second first hold capacitance area, the second active layer and the first first lower conductive layer overlap each other,
wherein, in the third first hold capacitance area, the second active layer and the first first interlayer conductive layer overlap each other,
wherein the first first hold capacitance area, the second first hold capacitance area, and the third first hold capacitance area overlap one another, and
wherein at least a portion of the first direct current line and at least a portion of the second direct current line are disposed in a same layer.

12. The display device of claim 8, comprising a second lower conductive layer disposed between the first lower conductive layer and the active layer,
wherein the first lower conductive layer includes a first lower conductive portion,
wherein the second lower conductive layer includes a second lower conductive portion,
wherein the first lower conductive portion defines at least a portion of the first direct current line,
wherein the second lower conductive portion is electrically connected to the first first interlayer conductive layer, and
wherein the first lower conductive portion and the second lower conductive portion overlap each other in the plan view such that the first hold capacitance is formed therebetween.

13. The display device of claim 12, wherein the storage capacitance area includes a second storage capacitance area, and
wherein, in the second storage capacitance area, a portion of the first gate conductive layer, which does not overlap the first active layer, overlaps the second lower conductive portion.

14. The display device of claim 8, wherein the pixels are arranged along a first direction, and
wherein the second direct current line extends in a second direction different from the first direction to overlap the sub-pixels.

15. The display device of claim 14, wherein the pixels include a first pixel, a second pixel, a third pixel, and a fourth pixel, which are arranged in the first direction,
wherein the second direct current line includes second direct current lines overlapping the sub-pixels of each of the first pixel, the second pixel, the third pixel, and the fourth pixel, and
wherein a first portion of the second direct current lines is applied with the reference power voltage,
a second portion of the second direct current lines is applied with the initialization power voltage,
a third portion of the second direct current lines is applied with the first power voltage, and
a fourth portion of the second direct current lines is applied with the second power voltage.

16. The display device of claim 15, wherein shapes of the second direct current line in sub-pixels which provide lights of different colors among the sub-pixels are different from each other such that values of the second hold capacitance are different from each other with respect to the sub-pixels which provide the lights of the different colors among the sub-pixels.

17. The display device of claim 16, wherein the sub-pixels include a first sub-pixel, a second sub-pixel, and a third sub-pixel,
wherein the first direct current line includes first direct current lines overlapping the first sub-pixel, the second sub-pixel, and the third sub-pixel, respectively,
wherein the first direct current lines in each of the first sub-pixel, the second sub-pixel, and the third sub-pixel include a first protrusion portion,
wherein the first direct current lines in the second sub-pixel in the first sub-pixel and the second sub-pixel include a second protrusion portion, and
wherein the first direct current line in the second sub-pixel includes a three protrusion portion.

18. The display device of claim 17, wherein at least a portion of the first direct current line, which is in a same layer as the second direct current line, has an island shape.

19. The display device of claim 17, wherein the sub-pixels include a first sub-pixel and a second sub-pixel,
wherein the pixels include a first pixel and a second pixel,
wherein the second direct current line of the first sub-pixel in the first pixel and the second direct current line of the first sub-pixel in the second pixel have a same shape as each other, and
wherein the second direct current line of the second sub-pixel in the first pixel and the second direct current line of the second sub-pixel in the second pixel have a same shape as each other.

20. An electronic device, comprising:
a processor which provides input image data;
a display device which displays an image based on the input image data, wherein the display device includes sub-pixel areas; and
a power supply which supplies a power to the display device,
wherein the display device comprises:
pixels each including sub-pixels; and
a first direct current line and a second direct current line,
wherein each of the sub-pixels includes:
a light emitting element; and
a sub-pixel circuit electrically connected to the light emitting element, wherein the sub-pixel circuit is electrically connected to the first direct current line and the second direct current line,
wherein the sub-pixel circuit includes:
a first transistor, wherein a gate electrode of the first transistor is electrically connected to a first node and one electrode of the first transistor is electrically connected to a second node;
a storage capacitor connected between the first node and the second node;
a first hold capacitor forming a first hold capacitance between the second node and the first direct current line; and
a second hold capacitor forming a second hold capacitance between the second node and the second direct current line, and
wherein, in sub-pixels which provide light of a same color among the sub-pixels, a sum of the first hold capacitance is equal to a sum of the second hold capacitance.
